(19) United States
(12) Patent Application Publication
(10) Pub. No.: US 2025/0323015 A1
(43) Pub. Date: Oct. 16, 2025

(54) ION IMPLANTER AND ION IMPLANTATION METHOD

(71) Applicant: Sumitomo Heavy Industries Ion Technology Co., Ltd., Tokyo (JP)

(72) Inventors: Kazuhisa ISHIBASHI, Ehime (JP); Takahiro MIYAMOTO, Ehime (JP)

(21) Appl. No.: 19/248,614

(22) Filed: Jun. 25, 2025

Related U.S. Application Data
(63) Continuation of application No. PCT/JP2023/041226, filed on Nov. 16, 2023.

(30) Foreign Application Priority Data
Dec. 26, 2022 (JP) 2022-208576

(51) Int. Cl. H01J 37/317; H01J 37/147; H01J 37/20

(52) U.S. Cl. CPC H01J 37/3171; H01J 37/147; H01J 37/20; H01J 2237/20207

(57) ABSTRACT

An ion implanter includes an ion source that generates ions, a beam transport device that transports an ion beam configured by the ions generated by the ion source to an implantation processing chamber, a workpiece holding device that is disposed in the implantation processing chamber and that holds a workpiece irradiated with the ion beam, a tilt angle adjusting device that adjusts a tilt angle of the workpiece held by the workpiece holding device, one or a plurality of processors, and one or a plurality of memories in which a program that is executable by the one or the plurality of processors is stored.

### CROSS-REFERENCE TO RELATED APPLICATIONS

This is a bypass continuation of International PCT Application No. PCT/JP2023/041226, filed on Nov. 16, 2023, which claims priority to Japanese Patent Application No. 2022-208576, filed on Dec. 26, 2022, which are incorporated by reference herein in their entirety.

### BACKGROUND

### Technical Field

Certain embodiments of the present invention relate to an ion implanter and an ion implantation method.

### Description of Related Art

The related art discloses an ion implanter that evaluates an ion beam under each of beam conditions by irradiating different regions on the same wafer with an ion beam under different beam conditions related to an implantation angle distribution (for example, FIGS. 23 and 24).

### SUMMARY

According to an aspect of the present invention, there is provided an ion implanter including an ion source that generates ions, a beam transport device that transports an ion beam configured by the ions generated by the ion source to an implantation processing chamber, a workpiece holding device that is disposed in the implantation processing chamber and that holds a workpiece irradiated with the ion beam, a tilt angle adjusting device that adjusts a tilt angle of the workpiece held by the workpiece holding device, one or a plurality of processors, and one or a plurality of memories in which a program that is executable by the one or the plurality of processors is stored. The program includes the following steps of (a) to (d): (a) adjusting, based on information on a first implantation angle of the ion beam with respect to the workpiece determined in advance in a first region of a processing surface of the workpiece, a tilt angle of the workpiece holding device to a first tilt angle corresponding to the first implantation angle with the tilt angle adjusting device, (b) transporting the ion beam with the beam transport device and irradiating the first region of the processing surface of the workpiece held at the first tilt angle by the workpiece holding device with the ion beam, (c) adjusting, based on information on a second implantation angle, which is different from the first implantation angle of the ion beam with respect to the workpiece and which is determined in advance in a second region different from the first region of the processing surface of the workpiece, the tilt angle of the workpiece holding device to a second tilt angle corresponding to the second implantation angle, which is different from the first tilt angle, with the tilt angle adjusting device, and (d) transporting the ion beam with the beam transport device and irradiating the second region of the processing surface of the workpiece held at the second tilt angle by the workpiece holding device with the ion beam.

According to this aspect, an implantation angle condition of the ion beam can be quickly changed by adjusting the tilt angle of the workpiece holding device.

According to another aspect of the present invention, there is provided an ion implanter. The device includes an ion source that generates ions, a beam transport device that transports an ion beam configured by the ions generated by the ion source to an implantation processing chamber and that includes a beam irradiation angle adjusting device which adjusts an irradiation angle of the ion beam with respect to a workpiece, which is disposed in the implantation processing chamber and irradiated with the ion beam, a beam irradiation angle acquisition device that measures the ion beam and that acquires information related to the irradiation angle of the ion beam to the workpiece, a workpiece holding device that holds the workpiece irradiated with the ion beam, one or a plurality of processors, and one or a plurality of memories in which a program that is executable by the one or the plurality of processors is stored. The program includes the following steps of (A) to (E): (A) measuring the ion beam transported to the implantation processing chamber and acquiring the information related to the irradiation angle of the ion beam to the workpiece with the beam irradiation angle acquisition device, (B) adjusting, based on information on a first implantation angle of the ion beam with respect to the workpiece determined in advance in a first region of a processing surface of the workpiece and the information related to the irradiation angle acquired in the step of (A), the irradiation angle of the ion beam to a first irradiation angle with the beam irradiation angle adjusting device, (C) transporting the ion beam with the beam transport device and irradiating the first region of the processing surface of the workpiece held by the workpiece holding device with the ion beam at the first irradiation angle, (D) adjusting, based on information on a second implantation angle which is different from the first implantation angle of the ion beam with respect to the workpiece and which is determined in advance in a second region different from the first region of the processing surface of the workpiece and the information related to the irradiation angle acquired in the step of (A), the irradiation angle of the ion beam to a second irradiation angle different from the first irradiation angle with the beam irradiation angle adjusting device, and (E) transporting the ion beam with the beam transport device and irradiating the second region of the processing surface of the workpiece held by the workpiece holding device with the ion beam at the second irradiation angle.

According to this aspect, the implantation angle condition of the ion beam can be quickly changed by adjusting the irradiation angle of the ion beam.

According to still another aspect of the present invention, there is provided an ion implantation method. The method in an ion implanter, including an ion source that generates ions, a beam transport device that transports an ion beam configured by the ions generated by the ion source to an implantation processing chamber, a workpiece holding device that is disposed in the implantation processing chamber and that holds a workpiece irradiated with the ion beam, and a tilt angle adjusting device that adjusts a tilt angle of the workpiece held by the workpiece holding device, includes performing the following steps of (a) to (d): (a) adjusting, based on information on a first implantation angle of the ion beam with respect to the workpiece determined in advance in a first region of a processing surface of the workpiece, a tilt angle of the workpiece holding device to a first tilt angle corresponding to the first implantation angle with the tilt angle adjusting device, (b) transporting the ion beam with the beam transport device and irradiating the first region of the processing surface of the workpiece held at the first tilt angle by the workpiece holding device with the ion beam, (c) adjusting, based on information on a second implantation angle, which is different from the first implantation angle of the ion beam with respect to the workpiece and which is determined in advance in a second region different from the first region of the processing surface of the workpiece, the tilt angle of the workpiece holding device to a second tilt angle corresponding to the second implantation angle, which is different from the first tilt angle, with the tilt angle adjusting device, and (d) transporting the ion beam with the beam transport device and irradiating the second region of the processing surface of the workpiece held at the second tilt angle by the workpiece holding device with the ion beam.

According to still another aspect of the present invention, there is provided an ion implantation method. The method in an ion implanter, including an ion source that generates ions, a beam transport device that transports an ion beam configured by the ions generated by the ion source to an implantation processing chamber and that includes a beam irradiation angle adjusting device which adjusts an irradiation angle of the ion beam with respect to a workpiece, which is disposed in the implantation processing chamber and irradiated with the ion beam, a beam irradiation angle acquisition device that measures the ion beam and that acquires information related to the irradiation angle of the ion beam to the workpiece, and a workpiece holding device that holds the workpiece irradiated with the ion beam, includes performing the following steps of (A) to (E): (A) measuring the ion beam transported to the implantation processing chamber and acquiring the information related to the irradiation angle of the ion beam to the workpiece with the beam irradiation angle acquisition device, (B) adjusting, based on information on a first implantation angle of the ion beam with respect to the workpiece determined in advance in a first region of a processing surface of the workpiece and the information related to the irradiation angle acquired in the step of (A), the irradiation angle of the ion beam to a first irradiation angle with the beam irradiation angle adjusting device, (C) transporting the ion beam with the beam transport device and irradiating the first region of the processing surface of the workpiece held by the workpiece holding device with the ion beam at the first irradiation angle, (D) adjusting, based on information on a second implantation angle which is different from the first implantation angle of the ion beam with respect to the workpiece and which is determined in advance in a second region different from the first region of the processing surface of the workpiece and the information related to the irradiation angle acquired in the step of (A), the irradiation angle of the ion beam to a second irradiation angle different from the first irradiation angle with the beam irradiation angle adjusting device, and (E) transporting the ion beam with the beam transport device and irradiating the second region of the processing surface of the workpiece held by the workpiece holding device with the ion beam at the second irradiation angle.

Any combination of the components described above and substitutions of expressions of the present invention between methods, devices, systems, recording media, computer programs, and the like are also effective as aspects of the present invention.

According to an aspect of the present invention, the implantation angle condition of the ion beam can be quickly changed through a simple method.

### BRIEF DESCRIPTION OF THE DRAWINGS

FIG. 1 is a top view showing a schematic configuration of an ion implanter.

FIG. 2 is a side view showing the schematic configuration of the ion implanter.

FIG. 3 is a perspective view showing an appearance of a beam irradiation angle acquisition device.

FIG. 4 is a cross-sectional view showing a configuration inside a casing of the beam irradiation angle acquisition device.

FIG. 5 schematically shows a range of a beam measurement surface in each electrode body.

FIG. 6 shows an example of a magnetic field distribution applied to each electrode body.

FIG. 7 schematically shows an example of an irradiation angle profile of an ion beam in an x-direction.

FIG. 8 schematically shows an example of an irradiation angle profile of an ion beam in a y-direction.

FIG. 9 is a functional block diagram of the ion implanter related to control of an implantation angle of the ion beam with respect to a wafer.

FIG. 10 schematically shows an example of definition of the implantation angle of the ion beam with respect to the wafer.

FIG. 11 is an example of a program of changing or adjusting the implantation angle of the ion beam with respect to the wafer by adjusting a tilt angle with a tilt angle adjusting device.

FIGS. 12A to 12D schematically show examples of a plurality of regions set on a wafer main surface.

FIG. 13 schematically shows an example of the plurality of regions set on the wafer main surface.

FIG. 14 shows an example of a correlation between a thermal-wave signal and the implantation angle.

FIGS. 15A to 15C show examples of a change aspect of the implantation angle or the tilt angle.

FIG. 16 is an example of a program for changing or adjusting the implantation angle of the ion beam with respect to the wafer by adjusting the irradiation angle with a beam irradiation angle adjusting device.

FIG. 17 is an example of a program for changing or adjusting the implantation angle of the ion beam with respect to the wafer by adjusting the tilt angle with the tilt angle adjusting device and adjusting the irradiation angle with the beam irradiation angle adjusting device.

FIGS. 18A and 18B schematically show examples of ion implantation processing for matching using a twist angle changing mechanism.

FIG. 19 schematically shows a correlation derived from ion implantation on one half surface of the wafer in FIG. 18A and ion implantation on the other half surface of the wafer in FIG. 18B, respectively, as individual graphs.

### DETAILED DESCRIPTION

In the ion implanter of the related art, it is necessary to prepare a large number of ion beams under beam conditions for evaluation (in one example, it is necessary to prepare a plurality of devices generating an ion beam).

The present invention has been devised in view of such a situation, and it is desirable to provide an ion implanter or the like that can quickly change an implantation angle condition of an ion beam through a simple method.

Hereinafter, an embodiment for carrying out the present invention will be described in detail with reference to the drawings. In the description or drawings, the same or equivalent components, members, and processing will be assigned with the same reference numerals, and redundant description thereof will be omitted. The scales and shapes of shown units are set for convenience in order to make the description easy to understand and are not to be understood as limiting unless stated otherwise. The embodiment is merely an example and does not limit the scope of the present invention. All features described in the embodiment and combinations thereof are not necessarily essential to the present invention.

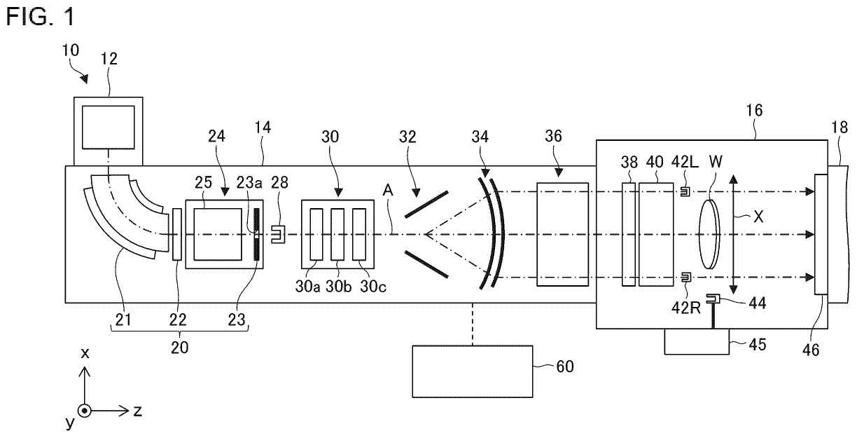

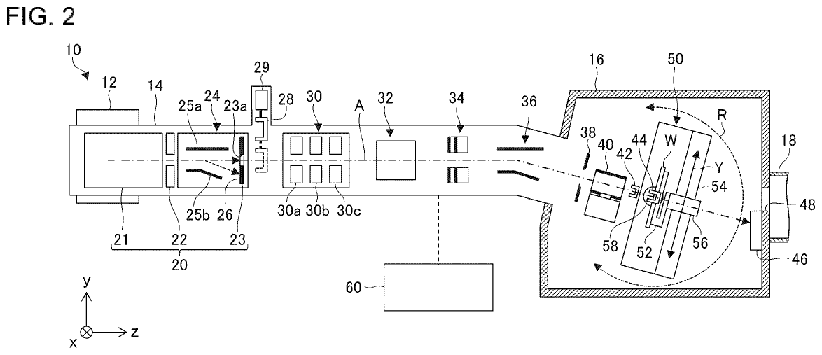

FIG. 1 is a top view showing a schematic configuration of an ion implanter 10 according to the embodiment of the present invention, and FIG. 2 is a side view showing the schematic configuration of the ion implanter 10. The ion implanter 10 is a device that performs ion implantation processing on a surface of a workpiece W. The workpiece W is, for example, a substrate such as a semiconductor wafer and a display device. In the present specification, the workpiece W will also be referred to as a wafer W for convenience. However, a target of the ion implantation processing is not intended to be limited to a specific object or a specific material such as a semiconductor wafer.

The ion implanter 10 can irradiate the entire surface to be processed of the wafer W with an ion beam by performing reciprocating scanning with the ion beam in one direction (hereinafter, also referred to as a scanning direction, a beam scanning direction, and a beam movement direction) and reciprocating the wafer W in a direction perpendicular to the scanning direction (hereinafter, also referred to as a reciprocating direction, a reciprocating movement direction, a wafer movement direction, and a movement direction). In the present specification, a traveling direction (hereinafter, also referred to as a beam traveling direction) of an ion beam traveling along a designed beamline A will be defined as a z-direction, and a plane perpendicular to the z-direction will be defined as an xy-plane. A scanning direction of an ion beam (beam movement direction) in a case where the workpiece W is scanned with the ion beam will be defined as an x-direction, and a y-direction perpendicular to the z-direction and the x-direction will be defined as the wafer movement direction. As described above, the reciprocating scanning with the ion beam is performed in the x-direction, and the reciprocating of the wafer W is performed in the y-direction.

The ion implanter 10 includes an ion generation device 12, a beamline unit 14, an implantation processing chamber 16, and a wafer transport device 18. The ion generation device 12 is an ion source that generates ions and supplies a generated ion beam to the beamline unit 14. The beamline unit 14 is a beam transport device that transports the ion beam configured by the ions generated by the ion generation device 12 to the implantation processing chamber 16. The wafer W, which is an ion implantation target, is accommodated in the implantation processing chamber 16, and ion implantation processing of irradiating the wafer W with the ion beam supplied from the beamline unit 14 is performed. The wafer transport device 18, which is a transport device, transports an unprocessed wafer before ion implantation processing into the implantation processing chamber 16 and transports a processed wafer after the ion implantation processing out of the implantation processing chamber 16. Although not shown, a vacuum evacuation system for providing a desired vacuum environment to the ion generation device 12, the beamline unit 14, the implantation processing chamber 16, and the wafer transport device 18 is provided in the ion implanter 10.

The beamline unit 14 includes a mass analyzing unit 20, a beam park device 24, a beam shaping unit 30, a beam scan unit 32, a beam parallelizing unit 34, and an angular energy filter (AEF) 36, in order from an upstream side of the beamline A. The upstream (side) of the beamline A is a side close to the ion generation device 12, and a downstream (side) of the beamline A is a side close to the implantation processing chamber 16 (or a beam stopper 46).

The mass analyzing unit 20 provided downstream of the ion generation device 12 selects or extracts a desired ion species used in ion implantation processing from ion beams generated by the ion generation device 12 through mass analysis. The mass analyzing unit 20 has a mass analyzing magnet 21, a mass analyzing lens 22, and a mass resolving aperture 23.

The mass analyzing magnet 21 applies a magnetic field to an ion beam extracted from the ion generation device 12 to deflect the ion beam along a different trajectory according to a value of a mass-to-charge ratio M=m/q (m is mass, and q is charge) of ions. For example, the mass analyzing magnet 21 applies a magnetic field in a −y-direction to the ion beam to deflect the ion beam in the x-direction perpendicular to the beam traveling direction (z-direction). A magnetic field intensity of the mass analyzing magnet 21 is adjusted such that ion species having the desired mass-to-charge ratio M can pass through the downstream mass resolving aperture 23.

The mass analyzing lens 22 is provided downstream of the mass analyzing magnet 21 (and upstream of the mass resolving aperture 23) and adjusts a focusing force/defocusing force (or a convergence degree/divergence degree of an ion beam) with respect to the ion beam. The mass analyzing lens 22 adjusts a focusing position of the ion beam passing through the mass resolving aperture 23 in the beam traveling direction (z-direction) and adjusts a mass resolution M/dM of the mass analyzing unit 20. The mass analyzing lens 22 may not be provided in the mass analyzing unit 20.

The mass resolving aperture 23 is provided at a position separated downstream from the mass analyzing lens 22. The mass resolving aperture 23 includes a rectangular opening 23a having a relatively short width in the x-direction and a relatively long height in the y-direction. Since a width direction (x-direction) of the opening 23a matches a beam deflection direction (x-direction) for the mass analyzing magnet 21, the width (a dimension in the x-direction) of the opening 23a mainly contributes to selection of the desired ion species according to the mass-to-charge ratio M in the mass resolving aperture 23.

The mass resolving aperture 23 may have a variable aperture width (the width of the opening 23a in the x-direction) for adjusting the mass resolution. For example, the mass resolving aperture 23 may be configured by two shield members that are movable relative to each other in an aperture width direction (x-direction), and the aperture width may be adjusted by changing an interval between the two shield members in the aperture width direction. In addition, the mass resolving aperture 23 may change the aperture width by switching a plurality of apertures having different aperture widths.

The beam park device 24 constitutes a beam deflection device that deflects an ion beam with at least one of an electric field and a magnetic field. Specifically, the beam park device 24 is switchable between an irradiation-enabled state where the ion beam is directed in an irradiation-enabled direction in which the wafer W can be irradiated with the ion beam and an irradiation-disabled state where the ion beam is directed in an irradiation-disabled direction in which the wafer W cannot be irradiated with the ion beam. In the example of FIG. 2, an arrow pointing toward an inside of the opening 23a of the mass resolving aperture 23 represents the irradiation-enabled direction, and an arrow pointing toward a beam dump 26 outside the opening 23a of the mass resolving aperture 23 represents the irradiation-disabled direction. Herein, the mass resolving aperture 23 is an aperture through which at least a part of the ion beam directed in the irradiation-enabled direction passes and is provided between the beam park device 24 which is the beam deflection device and a wafer holding device 52 (FIG. 2) which is a workpiece holding device to be described later.

The beam park device 24 in the irradiation-disabled state temporarily retracts an ion beam from the beamline A and shields the ion beam directed toward the downstream implantation processing chamber 16 (or the wafer W) with the beam dump 26. That is, the ion beam directed toward the irradiation-disabled direction collides with the beam dump 26 outside the opening 23a of the mass resolving aperture 23 and is blocked. The beam park device 24 can be disposed at any position on the beamline A, but is disposed between the mass analyzing lens 22 and the mass resolving aperture 23 in the example shown. Since a certain distance or more is required between the mass analyzing lens 22 and the mass resolving aperture 23 as described above, a space can be efficiently used by disposing the beam park device 24 therebetween. As a result, the size of the entire ion implanter 10 can be reduced by shortening the beamline A compared to a case where the beam park device 24 is disposed at another place.

The beam park device 24 shown in FIGS. 1 and 2 constitutes a beam deflection device of a type in which an ion beam is deflected by an electric field. The beam park device 24 includes a pair of park electrodes 25 (25a and 25b) and the beam dump 26. The pair of park electrodes 25a and 25b face each other in the y-direction with the beamline A interposed therebetween. The beam park device 24 switches an irradiation direction of the ion beam between the irradiation-enabled direction and the irradiation-disabled direction according to a change in an electric field in the y-direction caused by a change in a voltage applied between the pair of park electrodes 25a and 25b.

In the example of FIG. 2, when a voltage is not applied between the pair of park electrodes 25a and 25b (that is, when the voltage is substantially zero), a beam of a desired ion species to be used in ion implantation processing is not deflected, and the irradiation-enabled state is obtained in which the beam passes straight through the opening 23a of the mass resolving aperture 23 in the irradiation-enabled direction. On the other hand, when a voltage is applied between the pair of park electrodes 25a and 25b (that is, when a voltage has a significant non-zero value), a beam of the desired ion species to be used in ion implantation processing is deflected in the −y-direction, and the irradiation-disabled state is obtained in which the beam is shielded by colliding with the beam dump 26 outside the opening 23a of the mass resolving aperture 23 in the irradiation-disabled direction.

In the above example, an ion beam travels in the irradiation-enabled direction during non-deflection of an ion beam when a voltage is not applied between the pair of park electrodes 25a and 25b, and the ion beam travels in the irradiation-disabled direction during deflection of an ion beam when a voltage is applied between the pair of park electrodes 25a and 25b, but the ion beam during non-deflection may travel in the irradiation-disabled direction, and the ion beam during deflection may travel in the irradiation-enabled direction. In this case, for example, it is sufficient that the beam dump 26 is provided at the position of the opening 23a of the mass resolving aperture 23 in FIG. 2, and the opening 23a of the mass resolving aperture 23 may be provided at the position of the beam dump 26 in FIG. 2. In this case, a configuration downstream of the opening 23a is also provided on the beamline A of the (deflected) ion beam passing through the opening 23a.

In addition, an ion beam traveling in the irradiation-enabled direction and an ion beam traveling in the irradiation-disabled direction may be deflected by different voltages applied between the pair of park electrodes 25a and 25b. For example, in a case where the irradiation-enabled direction (a direction in which the opening 23a of the mass resolving aperture 23 is positioned) forms a first deflection angle θ1 with respect to a direction in which the ion beam is incident into the beam park device 24 and the irradiation-disabled direction (a direction in which the beam dump 26 is positioned) forms a second deflection angle θ2 significantly different from the first deflection angle θ1 with respect to the direction in which the ion beam is incident into the beam park device 24, a direction in which a beam of a desired ion species travels is switched between the irradiation-enabled direction and the irradiation-disabled direction by switching a voltage applied between the pair of park electrodes 25a and 25b between a first voltage V1 for realizing the first deflection angle θ1 and a second voltage V2 (≠V1) for realizing the second deflection angle θ2.

As described above, a facing direction of the pair of park electrodes 25a and 25b is the y-direction and is perpendicular to the beam deflection direction (x-direction) of the mass analyzing magnet 21. For this reason, a deflection voltage in the y-direction, which is applied between the pair of park electrodes 25a and 25b, does not hinder selection of a desired ion species according to the mass-to-charge ratio M performed by the mass analyzing magnet 21 along the x-direction.

In the example of FIG. 2, the first park electrode 25a is disposed above the beamline A in the gravity-direction (the facing direction of the first park electrode 25a and the second park electrode 25b), and the second park electrode 25b is disposed below the beamline A in the gravity-direction. The beam dump 26 provided downstream of the first park electrode 25a and the second park electrode 25b is disposed below the beamline A in the gravity-direction and below the opening 23a of the mass resolving aperture 23 in the gravity-direction. The beam dump 26 is, for example, a wall-shaped portion in which the opening 23a of the mass resolving aperture 23 is not formed. The beam dump 26 may be configured separately from the mass resolving aperture 23.

Hereinafter, the mass analyzing magnet 21 and the like in the mass analyzing unit 20 that can also function as the beam park device 24 and the beam deflection device as described above will be collectively referred to as the beam deflection device 24.

An injector Faraday cup 28 that also functions as a beam blocking mechanism is provided downstream of the mass resolving aperture 23. The injector Faraday cup 28 can be inserted into and removed from the beamline A by an operation of an injector drive unit 29. The injector drive unit 29 moves the injector Faraday cup 28 in a direction (for example, the y-direction) perpendicular to a direction in which the beamline A extends (z-direction). As shown by a broken line in FIG. 2, in a case where the injector Faraday cup 28 is disposed on the beamline A, an ion beam directed toward the downstream side is physically blocked, and thus a blocked state is obtained. On the other hand, as shown by a solid line in FIG. 2, in a case where the injector Faraday cup 28 is removed from the beamline A, a non-blocked state is obtained in which the ion beam directed toward the downstream side passes without being physically blocked. As described above, the injector Faraday cup 28 and the injector drive unit 29 function as the beam blocking mechanism switchable between the blocked state in which the ion beam is physically blocked and the non-blocked state in which the ion beam is caused to pass.

The injector Faraday cup 28 measures a beam current of an ion beam mass-analyzed by the mass analyzing unit 20. The injector Faraday cup 28 can acquire a mass-analyzed spectrum of the ion beam by measuring the beam current while changing a magnetic field intensity of the mass analyzing magnet 21. For example, the mass-analyzed spectrum is used in calculating mass resolution of the mass analyzing unit 20. Hereinafter, any mechanism that can physically block the ion beam, including the injector Faraday cup 28, will be collectively referred to as a beam blocking mechanism 28.

The beam shaping unit 30 includes a focusing/defocusing device, such as a focusing/defocusing quadrupole lens (Q lens), and shapes an ion beam that has passed through the mass analyzing unit 20 to have a desired cross-sectional shape. For example, the beam shaping unit 30 configured by an electric field type three-stage quadrupole lens (also referred to as a triplet Q lens) includes three quadrupole lenses 30a, 30b, and 30c. By using the three quadrupole lenses 30a to 30c, the beam shaping unit 30 can independently adjust convergence or divergence of the ion beam in the x-direction and the y-direction. The beam shaping unit 30 may include a magnetic field type lens device or may include a lens device that shapes the ion beam by using both an electric field and a magnetic field.

The beam scan unit 32 performs reciprocating scanning in a predetermined scanning angle range in the x-direction with an ion beam (a beam shaped by the beam shaping unit 30) with which the wafer W is irradiated by at least one of an electric field and a magnetic field. The beam scan unit 32 constitutes a beam scan device that scans with the ion beam in one direction (x-direction) perpendicular to the z-direction, which is a traveling direction thereof. The beam scan unit 32 can also be used as a beam deflection device that deflects the ion beam between the irradiation-enabled direction and the irradiation-disabled direction, instead of or in addition to the beam park device 24. The beam scan unit 32 includes a pair of scanning electrodes facing each other in the beam scanning direction (x-direction). The pair of scanning electrodes are connected to a variable voltage power supply (not shown) and periodically change a voltage applied between the pair of scanning electrodes to change an electric field between the electrodes and to deflect the ion beam at various angles in a zx-plane. As a result, the ion beam is used in scanning over the entire scanning range in the x-direction. In FIG. 1, the scanning direction and the scanning range of the ion beam are shown by an arrow X, and a plurality of trajectories of the ion beam in the scanning range is shown by a one-dot chain line.

The beam parallelizing unit 34 aligns the traveling direction of an ion beam for scanning by the beam scan unit 32 substantially parallel to a trajectory of the designed beamline A. The beam parallelizing unit 34 includes a plurality of arc-shaped parallelizing lens electrodes in which an ion beam passing aperture is provided in a central portion in the y-direction. The parallelizing lens electrode is connected to a high-voltage power supply (not shown) and applies an electric field generated by a voltage applied to the ion beam to the ion beam to align the traveling direction of the ion beam substantially parallel to the beamline A. The beam parallelizing unit 34 may be replaced with another type of beam parallelizing device, for example, a magnet device that uses a magnetic field. In addition, an Accel/Decel (AD) column (not shown) for accelerating or decelerating the ion beam may be provided downstream of the beam parallelizing unit 34.

The angular energy filter (AEF) 36 analyzes energy of an ion beam and deflects ions having required energy downward (−y-direction) to guide ions to the implantation processing chamber 16. The angular energy filter 36 includes a pair of AEF electrodes for electric field deflection, which are connected to a high-voltage power supply (not shown). In FIG. 2, a positive voltage is applied to an AEF electrode on the upper side (+y side), and a negative voltage is applied to an AEF electrode on the lower side (−y side), so that an ion beam of positive charges is deflected downward (in a case of an ion beam of negative charges, a negative voltage is applied to the AEF electrode on the upper side, and a positive voltage is applied to the AEF electrode on the lower side). The angular energy filter 36 may be configured by a magnet device for deflection by a magnetic field or may be configured in combination with the pair of AEF electrodes for electric field deflection and the magnet device for deflection by a magnetic field.

As described above, the beamline unit 14 supplies, to the implantation processing chamber 16, an ion beam with which the wafer W, which is a workpiece, is to be irradiated. The implantation processing chamber 16 includes an energy defining slit 38, a plasma shower device 40, a side cup 42 (42L, 42R), a profiler cup 44, and the beam stopper 46, in order from the upstream side of the beamline A. As shown in FIG. 2, the implantation processing chamber 16 includes a platen driving device 50 that holds one or a plurality of wafers W.

The energy defining slit 38 is provided on the downstream side of the angular energy filter 36 and analyzes energy of an ion beam incident into the wafer W together with the angular energy filter 36. The energy defining slit 38 is an energy defining slit (EDS) configured by a horizontally long slit in the beam scanning direction (x-direction). The energy defining slit 38 allows an ion beam having energy within a desired value or a desired range to pass therethrough toward the wafer W and shields the other ion beams.

The plasma shower device 40 is disposed on the downstream side of the energy defining slit 38. The plasma shower device 40 supplies low-energy electrons to an ion beam and/or the surface (wafer surface to be processed) of the wafer W according to a beam current of the ion beam to suppress accumulation of positive charges on the wafer surface to be processed caused by ion implantation (so-called charge-up). For example, the plasma shower device 40 includes a shower tube through which the ion beam passes and a plasma generating device that supplies electrons into the shower tube.

The side cup 42 (42R, 42L) measures a beam current of an ion beam during ion implantation processing on the wafer W. As shown in FIG. 1, the side cups 42R and 42L are disposed to be deviated to the right and left (the x-direction) from the wafer W disposed on the beamline A and are disposed at positions that do not block the ion beam directed toward the wafer W during the ion implantation. The ion beam is used in scanning in the x-direction beyond a range where the wafer W is positioned. Accordingly, a part of the beam used in scanning is incident into the side cups 42R and 42L even during the ion implantation. In this manner, the beam current during the ion implantation processing is measured by the side cups 42R and 42L. Since the wafer W, which is a workpiece, is not irradiated with the ion beam incident into the side cups 42R and 42L during the ion implantation, the side cups 42R and 42L constitute a beam current measuring device that measures the beam current of the ion beam directed toward the irradiation-disabled direction in which the wafer W is not irradiated. A beam current measuring device such as a Faraday cup may be provided on the beam dump 26 with which the ion beam directed toward the irradiation-disabled direction collides.

The profiler cup 44 measures a beam current on the wafer surface to be processed. The profiler cup 44 is movable in the x-direction by an operation of a drive unit 45, is retreated from an implantation region where the wafer W is positioned during ion implantation and is inserted into the implantation region when the wafer W is not in the implantation region. The profiler cup 44 driven in the x-direction can measure the beam current over the entire beam scanning range in the x-direction. The profiler cup 44 may include a plurality of Faraday cups arrayed in the x-direction such that the beam current can be simultaneously measured at a plurality of positions in the beam scanning direction (x-direction). Since the ion beam incident into the profiler cup 44 is incident into the implantation region where the wafer W, which is a workpiece, is positioned during the ion implantation, the profiler cup 44 constitutes a beam current measuring device that measures the beam current of the ion beam toward the irradiation-enabled direction in which the wafer W can be irradiated. The beam current measuring device such as a Faraday cup may be provided on the beam stopper 46 with which the ion beam directed toward the irradiation-enabled direction collides.

At least one of the side cup 42 and the profiler cup 44 may include a single Faraday cup for measuring a beam current or may include an angle measurement device for measuring angle information of an ion beam. For example, the angle measurement device includes an aperture and a plurality of current detecting units provided to be separated away from the aperture in the beam traveling direction (z-direction). The angle measurement device can measure an angle component or an angle distribution of the beam in the aperture width direction by causing a plurality of current detecting units arranged in the aperture width direction to measure the ion beam, which has passed through the aperture. At least one of the side cup 42 and the profiler cup 44 may include a first angle measuring device that can measure angle information in the x-direction and/or a second angle measuring device that can measure angle information in the y-direction.

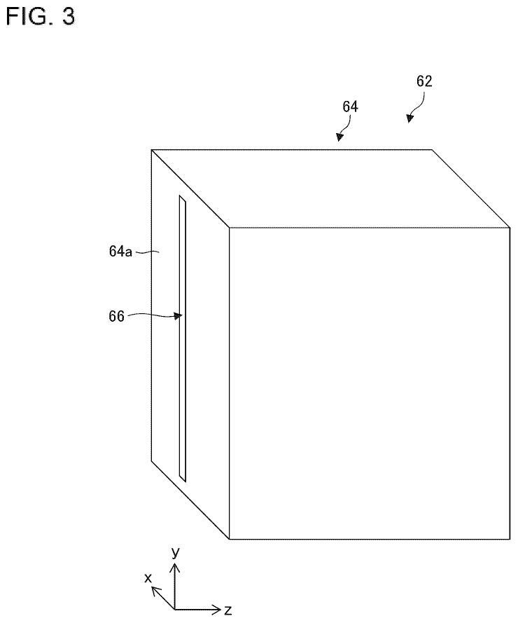

FIG. 3 is a perspective view showing an appearance of a beam irradiation angle acquisition device 62 which is an example of an angle measurement device of the side cup 42, the profiler cup 44, and/or the like, which is provided at any location where an ion beam can be measured. The beam irradiation angle acquisition device 62 includes a casing 64 and an aperture 66 provided in a front surface 64a of the casing 64. A plurality of electrode bodies are provided inside the casing 64. The beam irradiation angle acquisition device 62 is a device for measuring an ion beam and acquiring information (irradiation angle component) related to an irradiation angle of an ion beam to the wafer W, detects the ion beam passing through the aperture 66 with the plurality of electrode bodies, and acquires the irradiation angle component of the ion beam based on a detection result of each of the electrode bodies.

In the shown example, the traveling direction of an ion beam is defined as the z-direction, an aperture width direction of the aperture 66 is defined as the x-direction, and an aperture length direction of the aperture 66 is defined as the y-direction. The beam irradiation angle acquisition device 62 measures an irradiation angle component in the x-direction. The beam irradiation angle acquisition device 62 may measure an irradiation angle component in the y-direction in addition to or instead of the irradiation angle component in the x-direction. In this case, in addition to or instead of the beam irradiation angle acquisition device 62 including the aperture 66 extending in the y-direction as shown, a beam irradiation angle acquisition device including an aperture extending in the x-direction is used. In addition, when a beam irradiation angle acquisition device including an aperture extending in a direction intersecting both the x-direction and the y-direction is used, irradiation angle components in the x-direction and the y-direction can be measured through a single aperture.

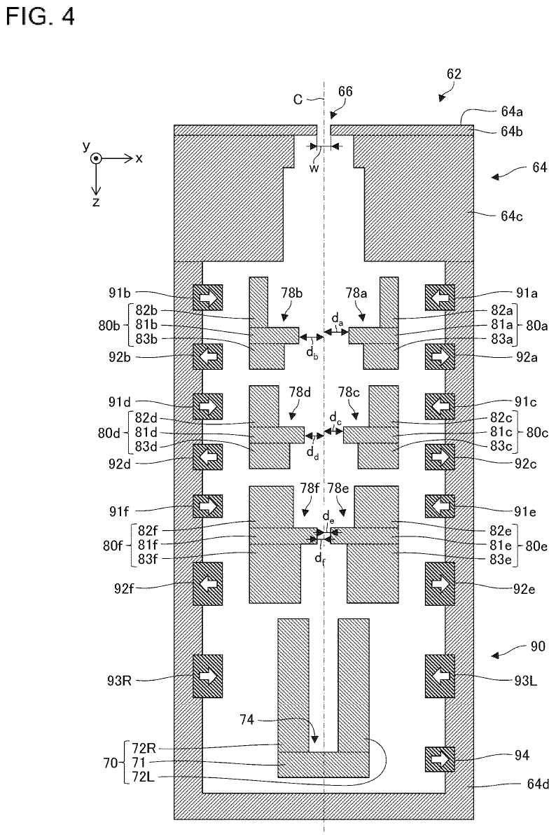

FIG. 4 is a cross-sectional view showing a configuration in the casing 64 of the beam irradiation angle acquisition device 62 and shows a cross section (zx-plane) perpendicular to the aperture length direction (y-direction) of the aperture 66. In the casing 64, a central electrode body 70, a plurality of side electrode bodies 80a, 80b, 80c, 80d, 80e, and 80f (collectively referred to as a side electrode body 80), and a magnet device 90 are provided.

The casing 64 includes an aperture portion 64b, an angle limiting portion 64c, and an electrode accommodation unit 64d. The aperture portion 64b includes the front surface 64a in which the aperture 66 is provided. The angle limiting portion 64c is provided on the downstream side of the aperture portion 64b in the beam traveling direction (z-direction). The angle limiting portion 64c shields a part of an ion beam directed toward the side electrode body 80 so that a beam having an irradiation angle component outside a measurement range is not incident into the side electrode body 80 (for example, the first side electrode body 80a and the second side electrode body 80b). The electrode accommodation unit 64d is provided on the downstream side of the angle limiting portion 64c in the beam traveling direction (z-direction). The electrode accommodation unit 64d includes a yoke for forming a magnetic circuit of the magnet device 90.

The central electrode body 70 is disposed on a center plane C extending from the aperture 66 in the beam traveling direction (z-direction) and is disposed most downstream separated away the aperture 66 in the beam traveling direction. The central electrode body 70 measures a beam of which an irradiation angle component in the aperture width direction (x-direction) is zero or extremely small, that is, a beam that substantially travels straight along the center plane C without being incident into the plurality of side electrode bodies 80a to 80f.

The central electrode body 70 includes a base portion 71 and a pair of extension portions 72L and 72R. The base portion 71 is disposed on the center plane C. The base portion 71 includes a beam measurement surface 74 exposed to a straight beam from the aperture 66. The pair of extension portions 72L and 72R extend from each end portion of the base portion 71 in the aperture width direction (x-direction) to the upstream side in the beam traveling direction (z-direction).

The plurality of side electrode bodies 80a to 80f are disposed between the aperture 66 and the central electrode body 70 and are disposed side by side symmetrically with respect to the center plane C in the aperture width direction (x-direction). In the shown example, three pairs of side electrode bodies, which are respectively configured by six side electrode bodies 80a to 80f, are disposed symmetrically with respect to the center plane C. Specifically, the first side electrode body 80a and the second side electrode body 80b are disposed side by side symmetrically with respect to the center plane C in the aperture width direction (x-direction), the third side electrode body 80c and the fourth side electrode body 80d are disposed side by side symmetrically with respect to the center plane C in the aperture width direction (x-direction), and the fifth side electrode body 80e and the sixth side electrode body 80f are disposed side by side symmetrically with respect to the center plane C in the aperture width direction (x-direction).

The first side electrode body 80a, the third side electrode body 80c, and the fifth side electrode body 80e disposed on the right side in FIG. 4 constitute side electrode bodies in a first group, which are arranged along the beam traveling direction (z-direction). The second side electrode body 80b, the fourth side electrode body 80d, and the sixth side electrode body 80f disposed on the left side in FIG. 4 constitute side electrode bodies in a second group, which are arranged along the beam traveling direction (z-direction). The side electrode bodies 80a, 80c, and 80d in the first group and the side electrode bodies 80b, 80d, and 80f in the second group are disposed symmetrically with respect to the center plane C.

Distances dₐ, d_{b}, d_{c}, d_{d}, dₑ, and d_{f} of the plurality of side electrode bodies 80a to 80f from the center plane C in the aperture width direction (x-direction) decrease as the side electrode bodies 80a to 80f are disposed closer to the downstream side in the beam traveling direction. The distances dₐ and d_{b} of the first side electrode body 80a and the second side electrode body 80b from the center plane C respectively are relatively large and are, for example, approximately 1.5 times an aperture width w of the aperture 66. The distances d_{c} and d_{d} of the third side electrode body 80c and the fourth side electrode body 80d from the center plane C respectively are approximately medium and are, for example, approximately 1 time (that is, the same as) the aperture width w of the aperture 66. The distances d_{c} and d_{f} of the fifth side electrode body 80e and the sixth side electrode body 80f from the center plane C respectively are relatively small and are, for example, approximately 0.5 times the aperture width w of the aperture 66.

The plurality of side electrode bodies 80a to 80f respectively include main bodies 81a, 81b, 81c, 81d, 81e, and 81f (also collectively referred to as a main body 81), upstream extension portions 82a, 82b, 82c, 82d, 82e, and 82f (also collectively referred to as an upstream extension portion 82), and downstream extension portions 83a, 83b, 83c, 83d, 83e, and 83f (also collectively referred to as a downstream extension portion 83). The plurality of side electrode bodies 80a to 80f respectively include beam measurement surfaces 78a, 78b, 78c, 78d, 78e, and 78f (collectively referred to as a beam measurement surface 78) into which a beam that has passed through the aperture 66 can be incident.

The main body 81 protrudes in the aperture width direction (x-direction) toward the center plane C. For this reason, a distance (for example, the distance dₐ) from the center plane C to the main body 81 is shorter than a distance from the center plane C to the upstream extension portion 82 or the downstream extension portion 83. The main body 81 is a portion into which a beam passing through the aperture 66 is mainly incident. Therefore, at least a part of a surface of the main body 81 on an aperture 66 side constitutes at least a part of the beam measurement surface 78 of the side electrode body 80.

The upstream extension portion 82 extends from the main body 81 to the upstream side. The upstream extension portion 82 is provided to be separated further away from the center plane C in the aperture width direction (x-direction) than the main body 81 is. The downstream extension portion 83 extends to the downstream side from the main body 81. The downstream extension portion 83 is provided to be separated further away from the center plane C in the aperture width direction (x-direction) than the main body 81 is. The length of each of the upstream extension portion 82 and the downstream extension portion 83 in the beam traveling direction (z-direction) is larger than the length of the main body 81 in the beam traveling direction (z-direction).

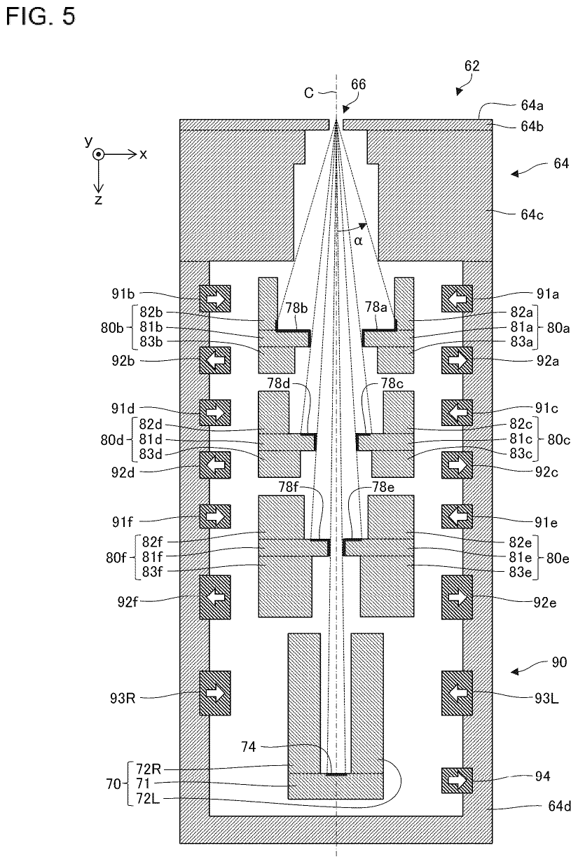

FIG. 5 schematically shows ranges of the beam measurement surfaces 74 and 78 of the electrode bodies 70 and 80, respectively. In the drawing, the ranges of the beam measurement surface 74 of the central electrode body 70 and the beam measurement surface 78 of each of the plurality of side electrode bodies 80 are shown by thick lines. The beam measurement surfaces 74 and 78 of the electrode bodies 70 and 80 are ranges of the surfaces of the electrode bodies 70 and 80 into which the beam which has passed through the aperture 66 can be incident, respectively.

Among beams passing through the aperture 66, a beam of which an irradiation angle component in the aperture width direction (x-direction) is larger than a is incident into an inner surface of the angle limiting portion 64c of the casing 64. For this reason, the beam of which the irradiation angle component in the aperture width direction (x-direction) is larger than α is not detected by the electrode bodies 70 and 80 and is not a measurement target of the beam irradiation angle acquisition device 62. On the other hand, a beam of which an irradiation angle component in the aperture width direction (x-direction) is α or less can be incident into any one of the central electrode body 70 and the plurality of side electrode bodies 80.

A beam of which an irradiation angle component is relatively large can be incident into the first beam measurement surface 78a of the first side electrode body 80a or the second beam measurement surface 78b of the second side electrode body 80b. The first beam measurement surface 78a is configured by a part of the surface of the first main body 81a and a part of the surface of the first upstream extension portion 82a. On the other hand, the beam is not incident into the surface of the first downstream extension portion 83a. This is because, in a case of being viewed from the aperture 66, the surface of the first downstream extension portion 83a is positioned on a back side of the first main body 81a that protrudes toward the center plane C. The first beam measurement surface 78a may be configured by only a part of the surface of the first main body 81a and may be configured such that the beam is not incident into the surface of the first upstream extension portion 82a. The second beam measurement surface 78b is formed at a position symmetrical to the first beam measurement surface 78a with respect to the center plane C.

A beam of which an irradiation angle component is medium can be incident into the third beam measurement surface 78c of the third side electrode body 80c or the fourth beam measurement surface 78d of the fourth side electrode body 80d. The third beam measurement surface 78c is configured by a part of the surface of the third main body 81c. On the other hand, the beam is not incident into the surfaces of the third upstream extension portion 82c and the third downstream extension portion 83c. This is because in a case of being viewed from the aperture 66, the surface of the third upstream extension portion 82c is positioned on the back side of the first side electrode body 80a, and the surface of the third downstream extension portion 83c is positioned on the back side of the third main body 81c that protrudes toward the center plane C. A part of the surface of the third upstream extension portion 82c may be configured to be the third beam measurement surface 78c. The fourth beam measurement surface 78d is formed at a position symmetrical to the third beam measurement surface 78c with respect to the center plane C.

A beam of which an irradiation angle component is relatively small can be incident into the fifth beam measurement surface 78e of the fifth side electrode body 80e or the sixth beam measurement surface 78f of the sixth side electrode body 80f. The fifth beam measurement surface 78e is configured by a part of the surface of the fifth main body 81e. On the other hand, the beam is not incident into surfaces of the fifth upstream extension portion 82e and the fifth downstream extension portion 83e. This is because in a case of being viewed from the aperture 66, the surface of the fifth upstream extension portion 82e is positioned on the back side of the third side electrode body 80c, and the surface of the fifth downstream extension portion 83e is positioned on the back side of the fifth main body 81e that protrudes toward the center plane C. A part of the surface of the fifth upstream extension portion 82e may be configured to be the fifth beam measurement surface 78e. The sixth beam measurement surface 78f is formed at a position symmetrical to the fifth beam measurement surface 78e with respect to the center plane C.

A beam of which an irradiation angle component is substantially zero can be incident into the beam measurement surface 74 of the central electrode body 70. The beam measurement surface 74 of the central electrode body 70 is configured by a part of the surface of the base portion 71 of the central electrode body 70. At least a part of inner surfaces of the extension portions 72L and 72R of the central electrode body 70 may be configured to be the beam measurement surface 74.

The magnet device 90 applies a magnetic field to the beam measurement surfaces 74 and 78 of the central electrode body 70 and the plurality of side electrode bodies 80, respectively. The magnet device 90 includes a plurality of first magnets 91a, 91b, 91c, 91d, 91e, and 91f (collectively referred to as a first magnet 91), a plurality of second magnets 92a, 92b, 92c, 92d, 92e, and 92f (collectively referred to as a second magnet 92), two third magnets 93L and 93R (collectively referred to as a third magnet 93), and one fourth magnet 94. Each of the magnets 91 to 94 is disposed to be separated further away from the center plane C in the aperture width direction (x-direction) than the plurality of side electrode bodies 80 than the central electrode body 70 and the plurality of side electrode bodies 80 are. Each of the magnets 91 to 94 is disposed on an inner peripheral surface of the electrode accommodation unit 64d of the casing 64. The shown arrows schematically show magnetization directions of the magnets 91 to 94, respectively.

The first magnet 91 and the second magnet 92 are configured to have opposite polarities to each other. The first magnet 91 has, for example, a first magnetic pole that is an N-pole and is disposed such that the first magnetic pole is on the inside. The second magnet 92 has, for example, a second magnetic pole that is an S-pole and is disposed such that the second magnetic pole is on the inside. Similarly, the third magnet 93 and the fourth magnet 94 are configured to have opposite polarities to each other. The third magnet 93 has, for example, a third magnetic pole that is an N-pole and is disposed such that the third magnetic pole is on the inside. The fourth magnet 94 has, for example, a fourth magnetic pole that is an S-pole and is disposed such that the fourth magnetic pole is on the inside. The first magnetic pole and the third magnetic pole may be the S-pole, and the second magnetic pole and the fourth magnetic pole may be the N-pole.

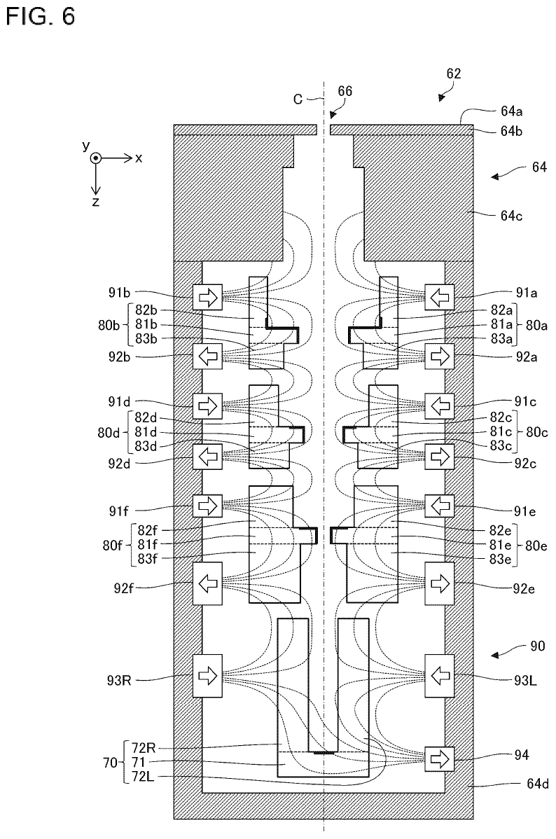

The plurality of first magnets 91 and the plurality of second magnets 92 are alternately disposed side by side in the beam traveling direction on the inner peripheral surface of the electrode accommodation unit 64d of the casing 64. A pair of such a first magnet 91 and such a second magnet 92 is disposed to correspond to each of the plurality of side electrode bodies 80a to 80f. For example, a pair of the first magnet 91a and the second magnet 92a is disposed in the vicinity of an outer peripheral side of the first side electrode body 80a. The first magnet 91 is disposed on the upstream side of the main body 81 of the corresponding side electrode body 80, and the second magnet 92 is disposed on the downstream side of the main body 81 of the corresponding side electrode body 80. The first magnet 91 and the second magnet 92 apply a magnetic field that is bent around an axis in the aperture length direction (y-direction) of the aperture 66 to the beam measurement surface 78 of the corresponding side electrode body 80 (for example, see FIG. 6 to be described later). Each of the plurality of first magnets 91 and the plurality of second magnets 92 is disposed symmetrically with respect to the center plane C, and thus, a magnetic field having a substantially symmetrical distribution in the aperture width direction (x-direction) is applied with the center plane C interposed therebetween.

The two third magnets 93L and 93R and the fourth magnet 94 are disposed in the vicinity of the outer peripheral side of the central electrode body 70. The two third magnets 93L and 93R are disposed symmetrically in the aperture width direction (x-direction) with the central electrode body 70 interposed therebetween (that is, the center plane C interposed therebetween). On the other hand, the fourth magnet 94 is disposed on only one side of the central electrode body 70 (that is, the center plane C). In the shown example, the third magnet 93L and the fourth magnet 94 are disposed on the downstream side of the second magnet 92e disposed in the vicinity of the outer peripheral side of the fifth side electrode body 80e. On the other hand, only the third magnet 93R is disposed on the downstream side of the second magnet 92f disposed in the vicinity of the outer peripheral side of the sixth side electrode body 80f, and the fourth magnet is not disposed. As a result, the two third magnets 93L and 93R and the fourth magnet 94 apply a magnetic field having an asymmetric distribution in the aperture width direction with the center plane C interposed therebetween (for example, see FIG. 6 to be described later).

FIG. 6 shows an example of a magnetic field distribution applied to each electrode body. In the drawing, hatching of the central electrode body 70 and the plurality of side electrode bodies 80 is omitted so that the magnetic field distribution inside each electrode body can be seen, and only a contour line is shown. As shown, a magnetic force line extends in an arc shape from the first magnet 91 toward the second magnet 92. The magnetic force line extending from the first magnet 91 toward the second magnet 92 is bent around the axis in a direction perpendicular to the paper surface of FIG. 6 (that is, the y-direction). In addition, a magnetic force line exiting from the beam measurement surface 78 of the side electrode body 80 is configured to be incident into the surface of the same side electrode body 80, and/or a magnetic force line incident into the beam measurement surface 78 of the side electrode body 80 is configured to exit from the surface of the same side electrode body 80. In addition, a magnetic force line passing through the vicinity of the beam measurement surface 78 of the side electrode body 80 is configured to exit from the surface of the same side electrode body 80 and to be incident into the surface of the same side electrode body 80.

With the beam irradiation angle acquisition device 62 having the configuration described above, an irradiation angle component of an ion beam passing through the aperture 66 in the aperture width direction (x-direction) can be measured by the central electrode body 70 and the plurality of side electrode bodies 80. A magnetic field distribution applied to the plurality of side electrode bodies 80 is substantially symmetrical along the aperture width direction with respect to the center plane C. Therefore, a magnetic force line in the vicinity of the center plane C faces a direction along the center plane C. As a result, an effect of application of a magnetic field on a trajectory of an ion beam passing through the vicinity of the center plane C can be reduced, and a measurement error caused by a change in a beam trajectory can be reduced. On the other hand, since a magnetic field distribution applied to the central electrode body 70 is asymmetric to the center plane C along the aperture width direction, the magnetic field distribution can affect the trajectory of the ion beam passing through the vicinity of the center plane C. However, since substantially all beams passing through the vicinity of the central electrode body 70 are detected by the central electrode body 70, a measurement error is not caused. As described above, with the beam irradiation angle acquisition device 62 having the configuration described above, a measurement error caused by secondary electrons can be effectively prevented from occurring by applying a magnetic field to each electrode body, and measurement accuracy of an irradiation angle component of the ion beam can be improved.

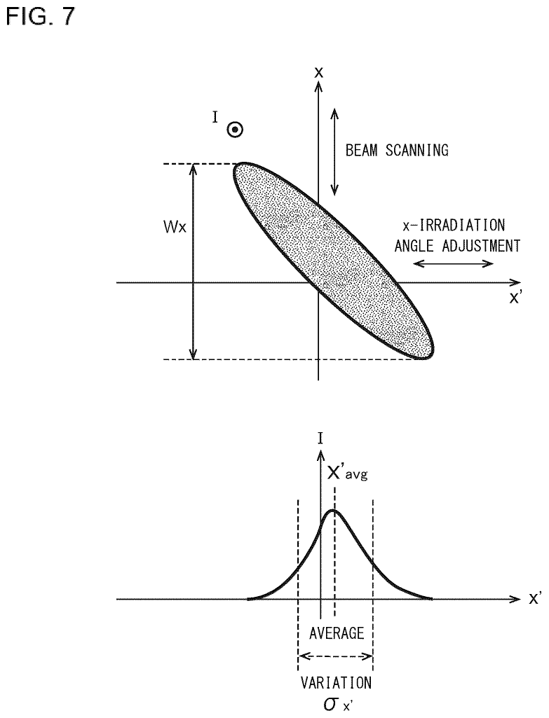

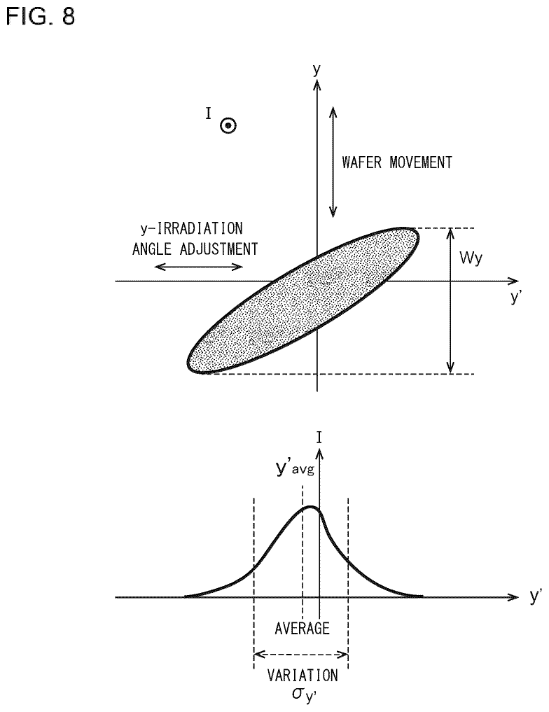

FIGS. 7 and 8 schematically show examples of an irradiation angle profile of an ion beam that can be acquired by the beam irradiation angle acquisition device 62. FIG. 7 shows an x-irradiation angle profile related to the x-direction which is the beam scanning direction, and FIG. 8 shows a y-irradiation angle profile related to the y-direction which is the wafer movement direction. The ion beam in the drawings is a spot beam having a substantially elliptical cross section having a width Wx in the x-direction and a width Wy in the y-direction.

The x-irradiation angle profile of the ion beam in FIG. 7 is a three-dimensional profile represented by an x-axis representing a position in the x-direction, an x′-axis representing an irradiation angle in the x-direction at each x position, and an I-axis representing an intensity of the ion beam at each point (x, x′). For example, when the ion beam is used in scanning in the x-direction by the beam scan unit 32 described above, the ion beam moves parallel to the x-axis on the x-irradiation angle profile. In addition, when the irradiation angle of the ion beam in the x-direction is adjusted by a beam irradiation angle adjusting device to be described later, the ion beam moves parallel to the x′-axis on the x-irradiation angle profile.

As will be described later, in the present embodiment, an implantation angle of an ion beam in the substantially x-direction with respect to the wafer W may be calculated in consideration of such a detailed x-irradiation angle profile. Alternatively, as schematically shown in the two-dimensional graph represented by the x′-axis and the I-axis, the implantation angle of the ion beam with respect to the wafer W in the substantially x-direction may be simply calculated using a representative value or a statistical value such as a weighted average x′_{avg} according to a beam intensity I of an x-irradiation angle x′ of the ion beam and/or a variation σ_{x′}.

The y-irradiation angle profile of the ion beam in FIG. 8 is a three-dimensional profile represented by a y-axis representing a position in the y-direction, a y′-axis representing an irradiation angle at each y-position in the y-direction, and an I-axis representing an intensity of the ion beam at each point (y, y′). For example, when the wafer W is driven in the y-direction by the reciprocating mechanism 54 described above, the ion beam moves relative to the wafer W in parallel with the y-axis on the y-irradiation angle profile. In addition, when the irradiation angle of the ion beam in the y-direction is adjusted by the beam irradiation angle adjusting device to be described later, the ion beam moves parallel to the y′-axis on the y-irradiation angle profile.

As will be described later, in the present embodiment, an implantation angle of the ion beam in the substantially y-direction with respect to the wafer W may be calculated in consideration of such a detailed y-irradiation angle profile. Alternatively, as schematically shown in the two-dimensional graph represented by the y′-axis and the I-axis, the implantation angle of the ion beam with respect to the wafer W in the substantially y-direction may be simply calculated using a representative value or a statistical value such as a weighted average y′_{avg} according to the beam intensity I of an y-irradiation angle y′ of the ion beam and/or a variation σ_{y′}.

In FIG. 2, the platen driving device 50 includes the wafer holding device 52, the reciprocating mechanism 54, a twist angle changing mechanism 56, and a tilt angle adjusting device 58.

The wafer holding device 52 for holding the wafer W to be irradiated with an ion beam includes an electrostatic chuck that is an electrostatic holding mechanism which constitutes a support mechanism supporting the wafer W and which holds the supported wafer W with electrostatic attraction. The wafer holding device 52 may include a temperature adjusting device for heating or cooling the wafer W to be subjected to ion implantation. The temperature adjusting device may be a heating device that heats the wafer W to a temperature higher than room temperature by 20° C. or more, 50° C. or more, or 100° C. or more or may be a cooling device that cools the wafer W to a temperature lower than room temperature by 20° C. or more, 50° C. or more, or 100° C. or more. The temperature of the wafer W affects a concentration distribution (implantation profile) of ions implanted into the wafer W and crystal defects (implantation damage) formed in the wafer W by the ion implantation. Processing of irradiating the wafer W having a temperature higher than room temperature with the ion beam is also called high-temperature implantation. In addition, processing of irradiating the wafer W having a temperature lower than room temperature with the ion beam is also called low-temperature implantation.

The reciprocating mechanism 54 is a drive mechanism that reciprocates the wafer holding device 52 including the support mechanism in a direction intersecting an ion beam. The reciprocating mechanism 54 reciprocates the wafer W held by the wafer holding device 52 in the y-direction by reciprocating the wafer holding device 52 including the support mechanism in the reciprocating direction (y-direction) perpendicular to the beam scanning direction (x-direction). In FIG. 2, a direction and a range of reciprocation of the wafer W are shown by an arrow Y.

The twist angle changing mechanism 56 is a mechanism that controls a rotation angle (twist angle) of the wafer W disposed at the wafer holding device 52 and adjusts a twist angle between an alignment mark provided at an outer peripheral portion of the wafer W and a reference position by rotating the wafer W with a normal line perpendicular to the wafer surface to be processed at the center of the wafer surface to be processed as a rotation axis. Herein, the alignment mark of the wafer W is, for example, a notch or an orientation flat provided in the outer peripheral portion of the wafer W and is reference for a crystal direction of the wafer W or an angular position in a circumferential direction of the wafer W. The twist angle changing mechanism 56 is provided between the wafer holding device 52 and the reciprocating mechanism 54 and is reciprocated by the reciprocating mechanism 54 together with the wafer holding device 52. The twist angle changing mechanism 56 can change the twist angle about a z-axis which is a third axis in a normal direction of a processing surface of the wafer W during movement of the wafer W in the y-direction with respect to an ion beam.

The tilt angle adjusting device 58 constituting an implantation angle adjusting mechanism is a mechanism that adjusts an inclination of the wafer W and adjusts a tilt angle between the traveling direction of an ion beam toward the wafer surface to be processed and the normal line of the wafer surface to be processed. In the example of FIG. 2, the tilt angle adjusting device 58 adjusts, as a tilt angle, a rotation angle of which an axis in the x-direction, among inclination angles of the wafer W, is a center axis of rotation. The tilt angle adjusting device 58 is provided between the reciprocating mechanism 54 and an inner wall of the implantation processing chamber 16 and adjusts the tilt angle of the wafer W by rotating the entire platen driving device 50 including the reciprocating mechanism 54 in an R-direction (FIG. 2).

The platen driving device 50 holds the wafer W such that the wafer Wis movable between an ion implantation position where the wafer W is irradiated with an ion beam and a transport position where the wafer W is transported into or out of the wafer transport device 18. That is, the platen driving device 50 constitutes a moving device that moves the wafer holding device 52 between the ion implantation position where the wafer W supported by the wafer holding device 52 is irradiated with the ion beam and the transport position where the wafer transport device 18 can transport the wafer W between the wafer holding device 52 and the wafer transport device 18. FIG. 2 shows a state where the wafer W and the wafer holding device 52 are at the ion implantation position, and the wafer holding device 52 holds the wafer W to intersect with the beamline A. The transport position of the wafer W corresponds to the position of the wafer holding device 52 when a transport mechanism or a transport robot provided in the wafer transport device 18 transports the wafer W into or out of a transport port 48.

The beam stopper 46 is provided most downstream of the beamline A and is attached to, for example, the inner wall of the implantation processing chamber 16. An ion beam in a case where the wafer W and the profiler cup 44 are not present on the beamline A is incident into the beam stopper 46. The beam stopper 46 is disposed near the transport port 48 that connects the implantation processing chamber 16 and the wafer transport device 18 and is provided at a position vertically below (−y-direction) the transport port 48 in the example of FIG. 2.

The ion implanter 10 further includes a control device 60 that controls the entire operation thereof. The control device 60 is realized by cooperation of a hardware resource, such as a central processing unit, a memory, an input device, and an output device of a computer and a peripheral unit connected to the computer, and software executed using the hardware resource. Regardless of a type or an installation place of the computer, each function of the control device 60 may be realized by the hardware resource of a single computer or may be realized by combining the hardware resources distributed to a plurality of computers.

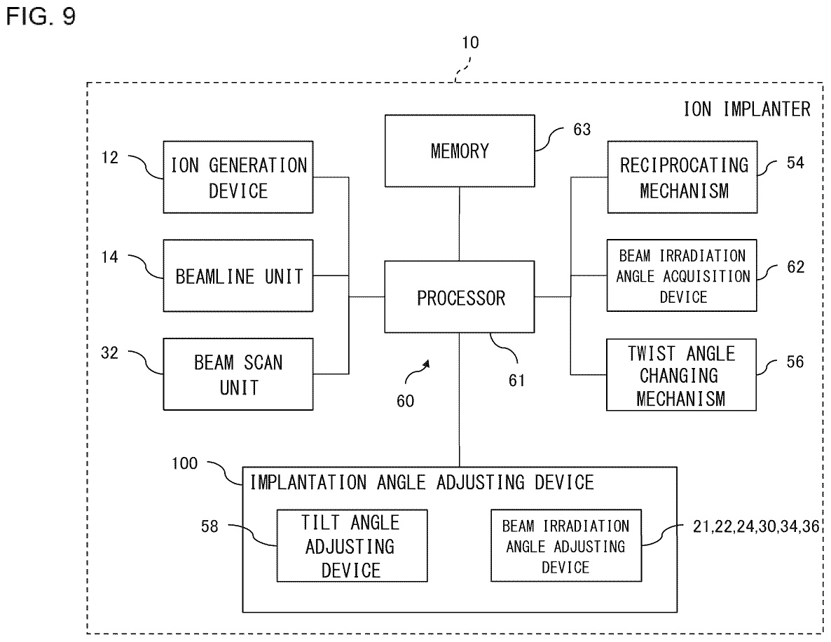

FIG. 9 is a functional block diagram of the ion implanter 10 related to control of an implantation angle of an ion beam with respect to the wafer W. The control device 60 of the ion implanter 10 includes a processor 61 and a memory 63. The processor 61 controls each of the units of the ion implanter 10 such as the ion generation device 12, the beamline unit 14, the beam scan unit 32, the reciprocating mechanism 54, the beam irradiation angle acquisition device 62, the twist angle changing mechanism 56, and an implantation angle adjusting device 100. The memory 63 stores a program that can be executed by the processor 61. The processor 61 controls each of the units of the ion implanter 10 based on the program stored in the memory 63.

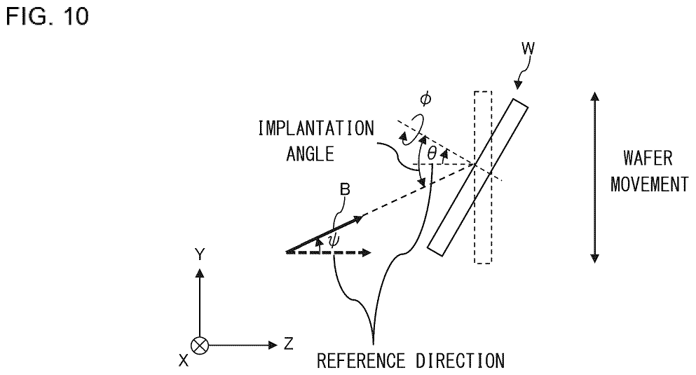

FIG. 10 schematically shows an example of definition of an implantation angle of an ion beam B with respect to the wafer W. In the drawing, an implantation angle about an X-axis in the beam scanning direction is shown as an example. However, an implantation angle about a Y-axis in the wafer movement direction is also defined in the same manner. In FIG. 10, a tilt angle θ of the wafer W and an irradiation angle ψ of the ion beam B are defined with the normal direction of the processing surface of the wafer W in a case where the tilt angle θ of the wafer W is zero as reference. The implantation angle of the ion beam B with respect to the wafer W is an angle formed by a normal line of the processing surface of the wafer W and an incident line of the ion beam B and is equal to a sum “θ+ψ” of the tilt angle θ of the wafer W and the irradiation angle ψ of the ion beam B. In a case where the incident line of the ion beam B matches the normal direction of the wafer W, that is, in a case where the ion beam B is incident into a front surface of the wafer W, the implantation angle “θ+ψ” of the ion beam B with respect to the wafer W is zero. The tilt angle θ and the irradiation angle w have positive and negative directions, and for example, a direction of an arrow in the drawing is defined as a positive direction. In addition, φ in FIG. 10 is the twist angle of the wafer W.

The implantation angle “θ+ψ” of the ion beam B with respect to the wafer W may be adjusted by only one of the tilt angle θ and the irradiation angle ψ. For example, in a case where the tilt angle θ is zero at all times, the implantation angle of the ion beam B with respect to the wafer W is equal to the irradiation angle ψ. Similarly, in a case where the irradiation angle ψ is zero at all times, the implantation angle of the ion beam B with respect to the wafer W is equal to the tilt angle θ.

In the present embodiment, based on the principle described above, an implantation angle of the ion beam B with respect to the wafer W is controlled based on the tilt angle θ and/or the irradiation angle ψ about two axes including the X-axis in the beam scanning direction and the Y-axis in the wafer movement direction. In particular, in the present embodiment, efficiency of work is improved by changing the implantation angle with respect to different regions on the same wafer in so-called matching performed before the device is manufactured in order to optimize an implantation parameter or a device manufacturing parameter of the ion implanter 10.

A specific example of changing processing of an implantation angle in matching is shown in a flowchart of a program (stored in one or a plurality of memories 63) that can be executed by one or a plurality of processors 61 shown in FIG. 9. For the purpose of simplifying description, a plurality of flowcharts are shown individually for convenience. However, processing of a part or all of the flowcharts is combined in any order insofar as they do not hinder each other. In addition, “S” in the flowcharts means a step or processing.

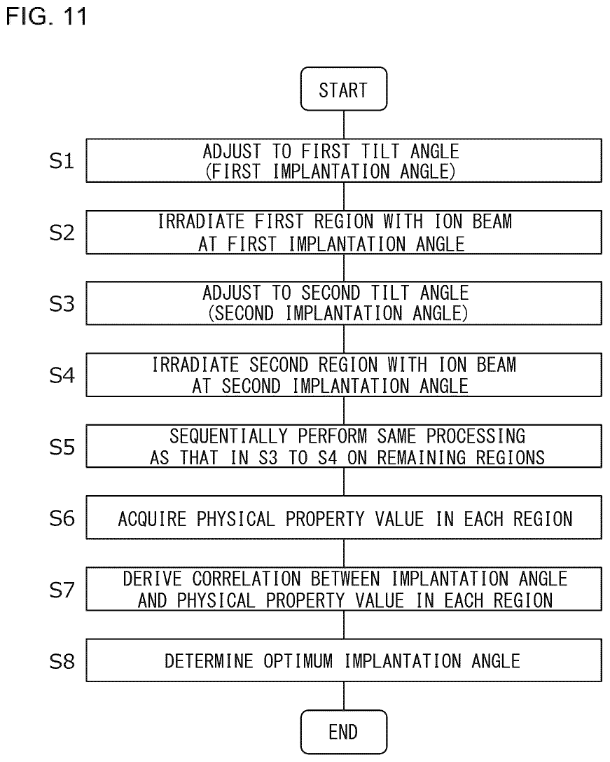

FIG. 11 is an example of a program for changing or adjusting the implantation angle “θ+ψ” of the ion beam B with respect to the wafer W by adjusting the tilt angle θ with the tilt angle adjusting device 58 constituting the implantation angle adjusting device 100 (FIG. 9). In the present example, while the tilt angle θ is controlled by the tilt angle adjusting device 58, the irradiation angle ψ is set to a constant value ψ₀ (for example, zero). Therefore, the implantation angle of the ion beam B with respect to the wafer W is represented by “θ+ψ₀”. During the movement of the wafer W in a Y-direction with respect to the ion beam B, the tilt angle adjusting device 58 may change a first axis tilt angle θ_{X} of the wafer W about the X-axis, which is a first axis perpendicular to the movement direction (Y-direction) or may change a second axis tilt angle θ_{Y} of the wafer W about the Y-axis, which is a second axis parallel to the movement direction (Y-direction). In the following description, the tilt angle θ indicates both or one of the first axis tilt angle θ_{X} and the second axis tilt angle θ_{Y} as a typical example.

In S1, (a) based on information on a first implantation angle “θ₁+ψ₀” of the ion beam B with respect to the wafer W determined in advance in a first region of the processing surface of the wafer W, the tilt angle adjusting device 58 adjusts the tilt angle θ of the wafer holding device 52 to a first tilt angle θ₁ corresponding to the first implantation angle “θ₁+ψ₀”. Herein, a plurality of regions including the first region and a second region to be described later are different regions on the processing surface of the wafer W. The shape, size, disposition, and the like of each region can be set in any manner.

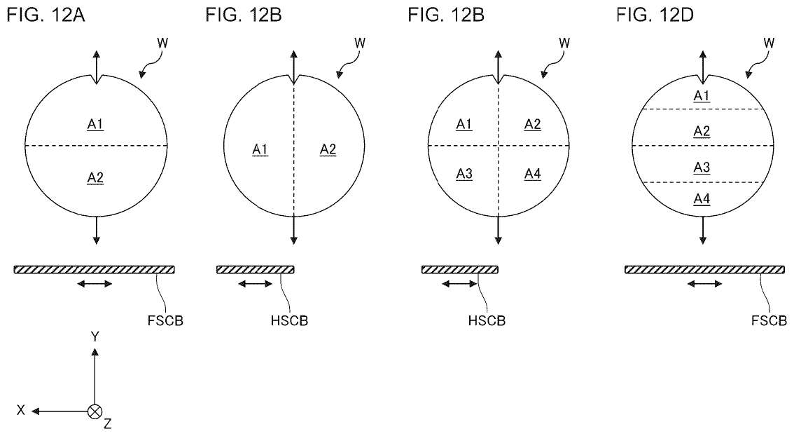

FIGS. 12A to 12D schematically show examples of a plurality of regions set on a wafer main surface which is the processing surface of the wafer W. FIG. 12A shows an example in which the wafer main surface is divided up and down (Y-direction), and a first region A1 is set on the upper side and a second region A2 is set on the lower side. FIG. 12B shows an example in which the wafer main surface is divided into right and left (X-direction), and the first region A1 is set on the left side and the second region A2 is set on the right side. FIG. 12C shows an example in which the wafer main surface is divided into four in up and down and right and left (the Y-direction and the X-direction), and the first region A1 is set on the upper left, the second region A2 is set on the upper right, a third region A3 is set on the lower left, and a fourth region A4 is set on the lower right. FIG. 12D shows an example in which the wafer main surface is divided into four in an up-down direction (Y-direction), and the first region A1, the second region A2, the third region A3, and the fourth region A4 are set in order in the up-down direction. The shown region setting is merely an example, and a plurality of regions may be set on the wafer main surface in an aspect different from the shown examples. The number of regions to be set may be 3 or may be 5 or more.

As will be described later, an ion beam having a different implantation angle is used to irradiate each region set on the wafer main surface. For example, the first region A1 in FIG. 12A is irradiated with an ion beam having the first implantation angle, and the second region A2 is irradiated with an ion beam having a second implantation angle different from the first implantation angle. In addition, in a case where the four regions A1 to A4 are set on the wafer main surface, four implantation angles different from each other are determined in advance.

In FIGS. 12B and 12C in which the wafer main surface is divided into right and left (X-direction), substantially half of the width of the wafer W, which is a workpiece, in the X-direction is scanned with an ion beam. For convenience, an ion beam for scanning the entire width of the wafer W in the X-direction will be referred to as a full scan beam (FSCB), and an ion beam for scanning substantially half of the width of the wafer W in the X-direction will be referred to as a half scan beam (HSCB). Switching between the FSCB and the HSCB is possible by appropriately controlling a periodic change in a voltage applied between the pair of scanning electrodes of the beam scan unit 32. In a case of switching ion implantation from the left half (A1/A3) to the right half (A2/A4) of the wafer W, the switching may be performed as the beam scan unit 32 controls a scanning range of the HSCB, or the switching may be performed as the twist angle changing mechanism 56 rotates a twist angle of the wafer W by 180 degrees.

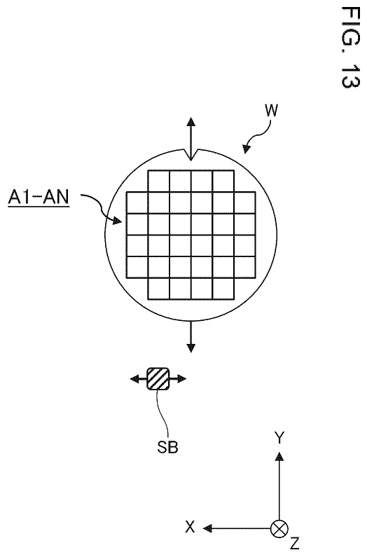

As shown in FIG. 13, a further larger number of regions A1 to AN (N is any natural number) may be set on the wafer main surface, for example, in a lattice shape. N implantation angles different from each other may be determined in the N regions, or the same implantation angle may be determined in some of a plurality of regions (preferably, a plurality of regions separated by a predetermined distance or more on the wafer main surface).

In a case where such lattice-shaped regions are set, a spot beam SB may be used as an ion beam for implanting ions into each region. It is preferable that the spot beam SB has the same shape and size as each region. In this case, each region is sequentially irradiated with the spot beam SB for a constant time once while the implantation angle is changed for each region by the implantation angle adjusting device 100.

In a case where a plurality of different regions are set side by side on the wafer W along the Y-direction, that is, the wafer movement direction, as shown in FIGS. 12A, 12C, 12D, and 13, an irradiation position of the ion beam B on the wafer W, of which the implantation angle (for example, the tilt angle θ) is adjusted by the implantation angle adjusting device 100 (for example, the tilt angle adjusting device 58), is preferably the same position on the beamline A regardless of the position of the wafer W in the Y-direction. Specifically, as can be understood from FIG. 10 as well, when the tilt angle θ of the wafer W is simply changed, there is a possibility in which the irradiation position of the ion beam B on the wafer W deviates forward and rearward along a Z-direction. Therefore, it is preferable that a mechanism that drives the wafer W itself in the Z-direction is provided to compensate for a change in the tilt angle θ and a deviation of the irradiation position of the ion beam B in the Z-direction caused by beam scanning in the X-direction and wafer movement in the Y-direction. With such a mechanism, the irradiation position of the ion beam B on the wafer W is the same position on the beamline A regardless of the position in the X-direction or the position in the Y-direction. As described above, the deviation of the irradiation position of the ion beam B in the Z-direction on the wafer W is eliminated, so that irradiation conditions (excluding the implantation angle) of the ion beam B at each irradiation position can be aligned. Accordingly, matching with high accuracy is possible. In a case where the mechanism for compensating for the deviation of the irradiation position of the ion beam B in the Z-direction is not provided, there is a possibility in which the deviation of the irradiation position of the ion beam B in the Z-direction affects the irradiation angle. In this case, an effect of the deviation of the irradiation position of the ion beam B in the Z-direction on the irradiation angle may be compensated based on calculation processing by the processor 61, using information on the irradiation angle acquired by the beam irradiation angle acquisition device 62.

In S2 in FIG. 11, (b) the ion beam B is transported by the beamline unit 14, and the first region of the processing surface of the wafer W held by the wafer holding device 52 at the first tilt angle θ₁ through S1 is irradiated with the ion beam B. As described above, the implantation angle of the ion beam B with respect to the first region in this case is the first implantation angle “θ₁+ψ₀” determined in advance. In the step of (b) as described above, the first region is irradiated with the ion beam B at the first implantation angle “θ₁+ψ₀” by the tilt angle adjusting device 58.

In S3, (c) based on information on the second implantation angle “θ₂+ψ₀” different from the first implantation angle “θ₁+ψ₀” of the ion beam B with respect to the wafer W determined in advance in the second region different from the first region on the processing surface of the wafer W, the tilt angle adjusting device 58 adjusts the tilt angle θ of the wafer holding device 52 to a second tilt angle θ₂ corresponding to the second implantation angle “θ₂+ψ₀”, which is different from the first tilt angle θ₁.

In S4, (d) the ion beam B is transported by the beamline unit 14, and the second region of the processing surface of the wafer W held by the wafer holding device 52 at the second tilt angle θ₂ through S3 is irradiated with the ion beam B. As described above, the implantation angle of the ion beam B with respect to the second region in this case is the second implantation angle “θ₂+ψ₀” determined in advance. In the step of (d) as described above, the second region is irradiated with the ion beam B at the second implantation angle “θ₂+ψ₀” by the tilt angle adjusting device 58. Between irradiation of the first region with the ion beam B at the first implantation angle “θ₁+ψ₀” in S2 and irradiation of the second region with the ion beam B at the second implantation angle “θ₂+ψ₀” in S4, the irradiation position of the ion beam B on the wafer W moves from the first region to the second region through beam scanning in the X-direction and/or wafer movement in the Y-direction.

In S5, the same processing as that in S3 and S4 (or the same processing as that in S1 and S2) is sequentially performed for the remaining regions (in the example of FIG. 13, N regions) set on the wafer W.

In S6, physical property values in each region on the wafer W including the first region and the second region after being irradiated with the ion beam B are individually acquired or measured. Examples of the physical property values include a sheet resistance, a spreading resistance, a thermal-wave signal measured based on a thermal wave method (thermally modulated optical reflectance), and a depth profile of an implanted impurity concentration measured by secondary ion mass spectrometry (SIMS). A wafer for device manufacturing may be used as the wafer W, the device may be actually manufactured, and characteristics (for example, electrical characteristics of a transistor, sensitivity characteristics of an image sensor, and the like) acquired or measured with respect to the device may be adopted as physical property values.

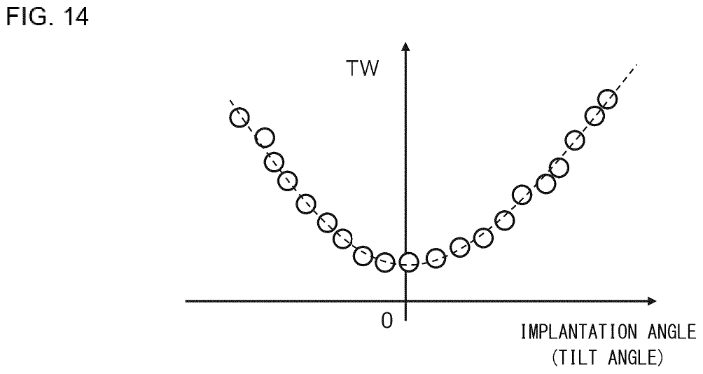

In S7, a correlation between a physical property value in each region acquired in S6 and an implantation angle in the region is derived. FIG. 14 shows an example of the correlation that can be derived in S7. In this drawing, the thermal-wave signal (TW) is given as an example of the physical property value, and a correlation between the thermal-wave signal and the implantation angle is obtained as a graph. This drawing shows a result in a case where the implantation angle is changed in a large number of regions and corresponds to a case where the region of FIG. 12D is set innumerable times and the implantation angle is continuously changed. In the example of FIG. 11, the implantation angle changes depending only on the tilt angle θ. Therefore, FIG. 14 may be understood as representing the correlation between the thermal-wave signal and the tilt angle θ.

In S8, an optimum implantation angle to be used in manufacture or mass production of the device by the ion implanter 10 is determined. In the example of FIG. 14, in a case where it is preferable for the manufacture of the device that the thermal-wave signal (TW) is minimized, the implantation angle or the tilt angle θ when the thermal-wave signal (TW) takes a minimum value is determined as an optimum value. As described above, in the manufacture of the device, the implantation angle determined as the optimum value in S8 is used for all the regions of all the wafers W used in the manufacture in principle. In a case of matching in FIG. 11, an effect on the physical property value can be comprehensively analyzed while changing the implantation angle or the tilt angle θ on one wafer W. Therefore, the number of wafers W consumed for matching can be reduced, and matching processing can be quickly completed by efficiently using a small number of wafers W.

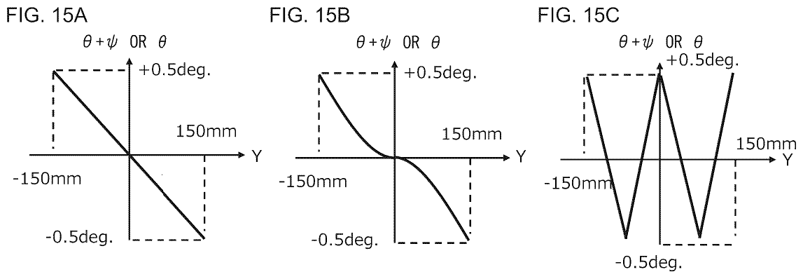

FIGS. 15A to 15C show examples of a change aspect of the implantation angle or the tilt angle θ by the implantation angle adjusting device 100 or the tilt angle adjusting device 58 in a case where the wafer W having a diameter of 300 mm is irradiated with the ion beam B while being moved in the Y-direction. The implantation angle or the tilt angle θ can also be discontinuously changed. However, in this example, a case where the implantation angle or the tilt angle θ is continuously changed is shown. Basically, the change aspect may be any change aspect and may be linear or straight as shown in FIG. 15A, may be non-linear or curved as shown in FIG. 15B, or may be a polygonal line as shown in FIG. 15C. In a case where it is expected that the optimum value of the implantation angle or the tilt angle θ is near zero as in the example of FIG. 14, a change in the implantation angle or the tilt angle θ with respect to the amount of wafer movement near zero (0 deg) is set to be gentle as in FIG. 15B. Thus, it is possible to increase information near zero and to obtain an accurate optimum value.

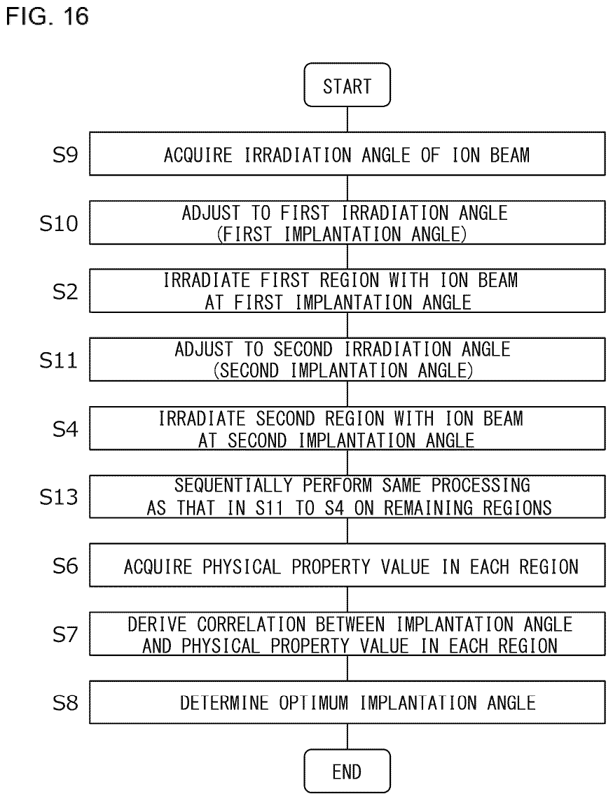

FIG. 16 is an example of a program for changing or adjusting the implantation angle “θ+ψ” of the ion beam B with respect to the wafer W by adjusting the irradiation angle ψ with the beam irradiation angle adjusting device constituting the implantation angle adjusting device 100 (FIG. 9). In the present example, the tilt angle θ is set to a constant value of θ₀ (for example, zero) while the irradiation angle ψ is controlled by the beam irradiation angle adjusting device. Therefore, the implantation angle of the ion beam B with respect to the wafer W is represented by “θ+ψ₀”. The beam irradiation angle adjusting device may change a first axis irradiation angle ψ_{X} of the ion beam B about the X-axis which is the first axis perpendicular to the movement direction (Y-direction) or may change a second axis irradiation angle ψ_{Y} of the ion beam B about the Y-axis which is the second axis parallel to the movement direction (Y-direction) during movement of the wafer W in the Y-direction with respect to the ion beam B. In the following description, the irradiation angle v indicates both or one of the first axis irradiation angle ψ_{X} and the second axis irradiation angle ψ_{Y} as a typical example.

The beam irradiation angle adjusting device is a device that adjusts the irradiation angle ψ of the ion beam B with respect to the wafer W. For example, the beam irradiation angle adjusting device can be configured by at least any one of the mass analyzing magnet 21, the mass analyzing lens 22, the beam park device 24, the beam shaping unit 30, the beam parallelizing unit 34, and the angular energy filter 36, all of which have been described above. The beam irradiation angle adjusting device may change a beam irradiation angle during movement of the wafer W in the Y-direction with respect to the ion beam B.

The mass analyzing magnet 21 functions as the beam deflection device that can adjust the irradiation angle ψ of the ion beam B with respect to the wafer W by deflecting the ion beam B in one direction (X-direction) perpendicular to the Z-direction which is the traveling direction. The mass analyzing magnet 21 may change a deflection angle of the ion beam B depending on the irradiation position of the ion beam B on the wafer W. The beam park device 24 and the angular energy filter 36 function as a beam deflection device that can adjust the irradiation angle ψ of the ion beam B with respect to the wafer W by deflecting the ion beam B in one direction (Y-direction) perpendicular to the Z-direction which is the traveling direction. The beam park device 24 and/or the angular energy filter 36 may change the deflection angle of the ion beam B depending on the irradiation position of the ion beam B on the wafer W.

The mass analyzing lens 22, the beam shaping unit 30, and the beam parallelizing unit 34 function as a convergent/divergent angle changing device that changes a convergent/divergent angle of the ion beam B in the X-direction and/or the Y-direction. The convergent/divergent angle changing devices may change the convergent/divergent angle of the ion beam B depending on the irradiation position of the ion beam B on the wafer W. When the convergent/divergent angle of the ion beam B is changed, the irradiation angle profiles of the ion beam B shown in FIGS. 7 and 8 are changed, and the irradiation angle ψ included therein is also changed.

The mass analyzing lens 22 and the beam shaping unit 30 function as a lens device that can adjust the irradiation angle ψ of the ion beam B with respect to the wafer W by adjusting the convergence/divergence of the ion beam B which is a spot beam. The beam parallelizing unit 34 functions as a lens device that can adjust the irradiation angle ψ of the ion beam B with respect to the wafer W by adjusting parallelism of the ion beam B which is a scan beam.

In FIG. 16, the same steps or processing will be assigned with the same reference numerals as those in FIG. 11 described above, and redundant description thereof will be omitted. In S9, (A) the ion beam B transported to the implantation processing chamber 16 is measured, and information related to the irradiation angle ψ of the ion beam B to the wafer W is acquired by the beam irradiation angle acquisition device 62. In this case, the beam irradiation angle acquisition device 62 can function as an irradiation angle distribution acquisition unit that acquires a distribution depending on the irradiation position of the irradiation angle ψ of the ion beam B at the irradiation position with respect to the wafer W by measuring the ion beam B while moving the profiler cup 44 (FIG. 1) provided with the beam irradiation angle acquisition device 62 in the X-direction.

In S10, (B) the irradiation angle ψ of the ion beam B is adjusted to a first irradiation angle ψ₁ by the beam irradiation angle adjusting devices 21, 22, 24, 30, 34, and 36 based on information on the first implantation angle “θ₀+ψ₁” of the ion beam B with respect to the wafer W determined in advance in the first region of the processing surface of the wafer W and the information on the irradiation angle ψ acquired in the step of (A).

In S2, (C) the ion beam B is transported by the beamline unit 14, and the first region of the processing surface of the wafer W held by the wafer holding device 52 is irradiated with the ion beam B at the first irradiation angle ψ₁. As described above, the implantation angle of the ion beam B with respect to the first region in this case is the first implantation angle “θ₀+ψ₁” determined in advance. In the step of (C) as described above, as the first region is irradiated with the ion beam B at the first irradiation angle ψ₁ by the beamline unit 14, irradiation with the ion beam B at the first implantation angle “θ₀+ψ₁” is performed.

In S11, (D) the irradiation angle ψ of the ion beam B is adjusted to a second irradiation angle ψ₂ different from the first irradiation angle ψ₁ by the beam irradiation angle adjusting devices 21, 22, 24, 30, 34, and 36 based on information on the second implantation angle “θ₀+ψ₂”, which is different from the first implantation angle “θ₀+ψ₁” of the ion beam B with respect to the wafer W and which is determined in advance in the second region different from the first region of the processing surface of the wafer W and the information related to the irradiation angle ψ acquired in the step of (A).

In S4, (E) the ion beam B is transported by the beamline unit 14, and the second region of the processing surface of the wafer W held by the wafer holding device 52 is irradiated with the ion beam B at the second irradiation angle ψ₂. As described above, the implantation angle of the ion beam B with respect to the second region in this case is the second implantation angle “θ₀+ψ₂” determined in advance. In the step of (E) as described above, as the second region is irradiated with the ion beam B at the second irradiation angle ψ₂ by the beamline unit 14, irradiation with the ion beam B at the second implantation angle “θ₀+ψ₂” is performed. Between irradiation of the first region with the ion beam B at the first implantation angle “θ₁+ψ₀” in S2 and irradiation of the second region with the ion beam B at the second implantation angle “θ₀+ψ₂” in S4, the irradiation position of the ion beam B on the wafer W moves from the first region to the second region through beam scanning in the X-direction and/or wafer movement in the Y-direction.

In S13, the same processing as that in S11 and S4 (or the same processing as that in S10 and S2) is sequentially performed for the remaining regions (in the example of FIG. 13, N regions) set on the wafer W.

In S6, physical property values in each region on the wafer W including the first region and the second region after being irradiated with the ion beam B are individually acquired or measured. In S7, a correlation between the physical property value in each region acquired in S6 and the implantation angle or the irradiation angle ψ in each region is derived. In S8, an optimum implantation angle or an optimum irradiation angle ψ to be used in the manufacture or mass production of the device by the ion implanter 10 is determined.

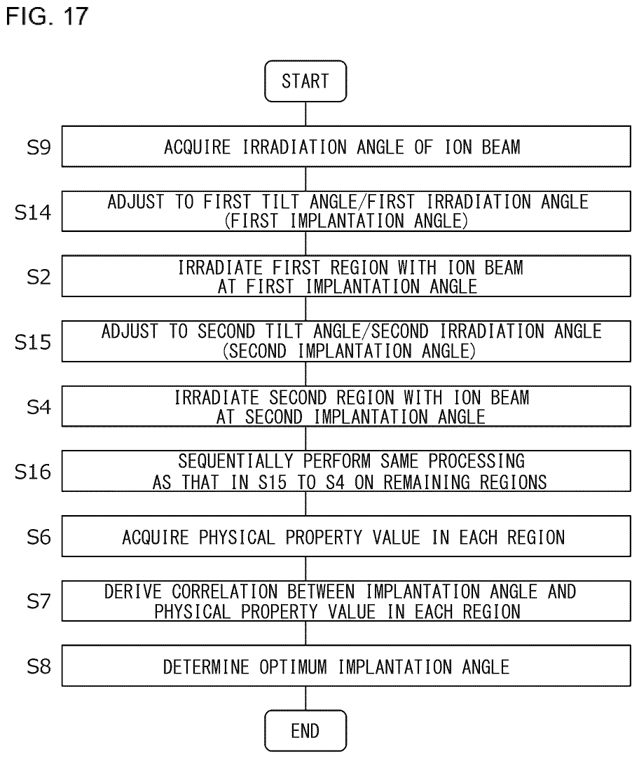

FIG. 17 is an example of a program in which the implantation angle “θ+ψ” of the ion beam B with respect to the wafer W is changed or adjusted by adjusting the tilt angle θ with the tilt angle adjusting device 58 and by adjusting the irradiation angle ψ with the beam irradiation angle adjusting device. The same steps or processing will be assigned with the same reference numerals as those in FIG. 11 and/or 16 described above, and redundant description thereof will be omitted.

In S9, (A) the ion beam B transported to the implantation processing chamber 16 is measured, and information related to the irradiation angle ψ of the ion beam B with respect to the wafer W is acquired by the beam irradiation angle acquisition device 62.

In S14, (B) the irradiation angle ψ of the ion beam B is adjusted to the first irradiation angle ψ₁ by the beam irradiation angle adjusting devices 21, 22, 24, 30, 34, and 36 based on information on the first implantation angle “θ₁+ψ₁” of the ion beam B with respect to the wafer W determined in advance in the first region of the processing surface of the wafer W and the information related to the irradiation angle ψ acquired in the step of (A). In addition, in S14, (F) based on information on the first implantation angle “θ₁+ψ₁” of the ion beam B with respect to the wafer W determined in advance in the first region of the processing surface of the wafer W, the tilt angle adjusting device 58 adjusts the tilt angle θ of the wafer holding device 52 to the first tilt angle θ₁ corresponding to the first implantation angle “θ₁+ψ₁”.

In S2, (C) the ion beam B is transported by the beamline unit 14, and the first region of the processing surface of the wafer W held by the wafer holding device 52 at the first tilt angle θ₁ is irradiated with the ion beam B at the first irradiation angle ψ₁ through S14. As described above, the implantation angle of the ion beam B with respect to the first region in this case is the first implantation angle “θ₁+ψ₁” determined in advance. In the step of (C) as described above, the first region is irradiated with the ion beam B at the first implantation angle “θ₁+ψ₁” through the steps of (B) and (F).

In S15, (D) the irradiation angle ψ of the ion beam B is adjusted to a second irradiation angle ψ₂ different from the first irradiation angle ψ₁ by the beam irradiation angle adjusting devices 21, 22, 24, 30, 34, and 36 based on information on the second implantation angle “θ₂+ψ₂” which is different from the first implantation angle “θ₁+ψ₁” of the ion beam B with respect to the wafer W and which is determined in advance in the second region different from the first region of the processing surface of the wafer W and the information related to the irradiation angle y acquired in the step of (A). In addition, in S15, (G) based on information on the second implantation angle “θ₂+ψ₂” of the ion beam B with respect to the wafer W determined in advance in the second region of the processing surface of the wafer W, the tilt angle adjusting device 58 adjusts the tilt angle θ of the wafer holding device 52 to the second tilt angle θ₂ corresponding to the second implantation angle “θ₂+ψ₂”.

In S4, (E) the ion beam B is transported by the beamline unit 14, and the second region of the processing surface of the wafer W held by the wafer holding device 52 at the second tilt angle θ₂ is irradiated with the ion beam B at the second irradiation angle ψ₂ through S15. As described above, the implantation angle of the ion beam B with respect to the second region in this case is the second implantation angle “θ₂+ψ₂” determined in advance. In the step of (E) as described above, the second region is irradiated with the ion beam B at the second implantation angle “θ₂+ψ₂” through the steps of (D) and (G). Between irradiation of the first region with the ion beam B at the first implantation angle “θ₁+ψ₁” in S2 and irradiation of the second region with the ion beam B at the second implantation angle “θ₂+ψ₂” in S4, the irradiation position of the ion beam B on the wafer W moves from the first region to the second region through beam scanning in the X-direction and/or wafer movement in the Y-direction.

In S16, processing of S15 and S4 (or the processing of S14 and S2) are sequentially performed for all the remaining regions (in the example of FIG. 13, N regions) on the wafer W.

In S6, physical property values in each region on the wafer W including the first region and the second region after being irradiated with the ion beam B are individually acquired or measured. In S7, a correlation between the physical property value in each region acquired in S6 and the implantation angle (a combination of the tilt angle θ and the irradiation angle ψ) in each region is derived. In S8, an optimum implantation angle (the combination of the tilt angle θ and the irradiation angle ψ) to be used in manufacture or mass production of the device by the ion implanter 10 is determined.

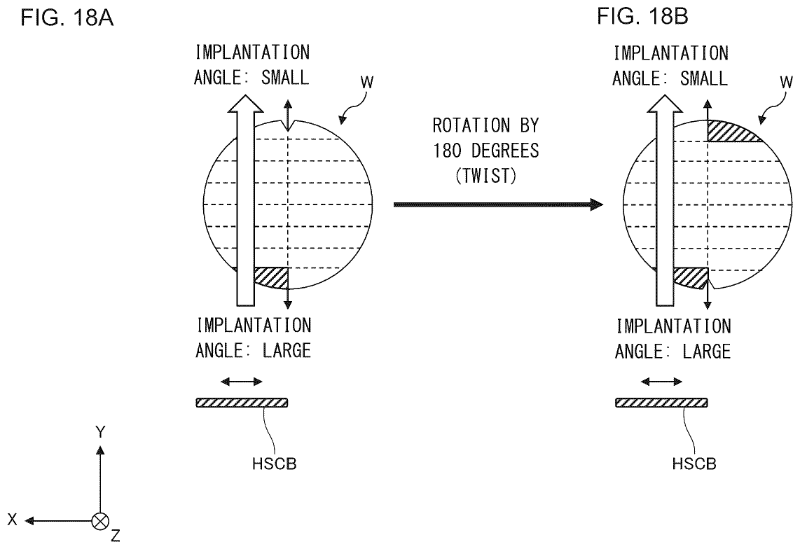

FIGS. 18A and 18B schematically show examples of ion implantation processing for matching using the twist angle changing mechanism 56. In this example, the ion implantation processing is performed at a substantially opposite implantation angle for each half surface of the wafer W in order to remove an effect that a crystal orientation of the wafer W can have on matching accuracy. For example, as shown in FIG. 18A, as the wafer W is reciprocated in the Y-direction, one half surface of the wafer W is irradiated with the half scan beam HSCB. In this case, the implantation angle of the half scan beam HSCB with respect to the wafer W is controlled by the implantation angle adjusting device 100 to be sequentially reduced from the bottom toward the top in the Y-direction. For example, the implantation angle at a lower end is a maximum +0.5 deg, and the implantation angle at an upper end is a minimum −0.5 deg.

Next, when the twist angle changing mechanism 56 rotates the wafer W by 180 degrees, as shown in FIG. 18B, the other half surface of the wafer W which is not implanted comes into a scan range of the half scan beam HSCB. Then, the other half surface of the wafer W which is not implanted is irradiated with the half scan beam HSCB in the same aspect as that in FIG. 18A by reciprocating the wafer W in the Y-direction. Hatching is exemplarily attached to a region where the ion implantation is performed at a maximum implantation angle (for example, +0.5 deg) in FIGS. 18A and 18B. As will be understood hereinafter, ion implantation processing is performed on each of the half surfaces of the wafer W at a substantially opposite implantation angle. A change in the implantation angle of the half scan beam HSCB may be opposite, and for example, the implantation angle at the lower end may be a minimum −0.5 deg, and the implantation angle at the upper end may be a maximum +0.5 deg.

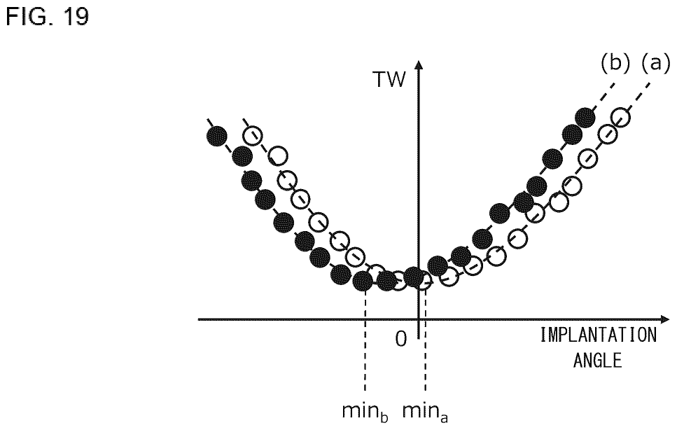

FIG. 19 schematically shows correlations (S7) derived from ion implantation into one half surface of the wafer W in FIG. 18A and ion implantation into the other half surface of the wafer W in FIG. 18B, respectively, as individual graphs. The graph according to FIG. 18A is plotted with white circles and takes a minimum value at an implantation angle minₐ. The graph according to FIG. 18B is plotted with black circles and takes a minimum value at an implantation angle min_{b}. As in this example, in a case where an effect of the crystal orientation of the wafer W cannot be ignored, a slightly different correlation can be derived on each half surface of the wafer W. In such a case, in S8 described above, for example, an average value “(minₐ+min_{b})/2” of implantation angles when a thermal-wave signal takes a minimum value in each graph may be determined as an optimum implantation angle to be used in manufacture or mass production of the device by the ion implanter 10.

A correlation with the implantation angle as in FIG. 14 or 19 may be accurately derived through analysis of the irradiation angle profiles as in FIGS. 7 and 8 acquired by the beam irradiation angle acquisition device 62 (S9). As shown in FIGS. 7 and 8, the ion beam B (for example, the spot beam SB) has significant widths Wx and Wy in the x-direction and the y-direction and has an irradiation angle distribution or an irradiation angle component different from each other at each (x, y) position. For this reason, in each region on the wafer W as shown in FIGS. 12A to 13, in a strict sense, irradiation with various irradiation angle components having various intensities are performed. Therefore, for example, by using the irradiation angle profiles as shown in FIGS. 7 and 8, a cumulative intensity of each irradiation angle component with which each region on the wafer W is irradiated can be accurately calculated. Alternatively, each region on the wafer W may be handled in a transverse manner, and the cumulative intensity of each irradiation angle component with respect to the entire wafer W may be extracted. By comparing such detailed data with the physical property value of each region measured in S6 described above, an effect of each irradiation angle component on the physical property value can be accurately visualized, for example, in the form of a graph as shown in FIG. 14 or 19.

The present invention has been described hereinbefore based on the embodiment. It is clear for those skilled in the art that the embodiment is an example, various modification examples are possible for a combination of each component and each processing process, and such modification examples are also within the scope of the present invention.

In FIGS. 12A to 12D, a configuration using a scan beam with which the wafer W is scanned in the X-direction as a spot beam has been described. However, the present disclosure may be applied to a configuration using a ribbon beam that has a spread in the X-direction. The scan beam configured by the spot beam for scanning in the X-direction can be considered as a pseudo ribbon beam, and a configuration using the scan beam can be applied to a configuration using the ribbon beam mostly as it is. For example, in the ion implanter shown in FIGS. 1 and 2, the ribbon beam having the spread of the ion beam in the X-direction is shaped by using the beam shaping unit 30. As scanning with an ion beam by the beam scan unit 32 is stopped, the ribbon beam can also be used. As an ion implanter dedicated to a ribbon beam, a configuration disclosed in Japanese Patent No. 5655881 or Japanese Patent No. 7127210 is given as an example.

A functional configuration of each device described in the embodiment can be realized by a hardware resource or a software resource or by cooperation of the hardware resource and the software resource. A processor, a ROM, a RAM, or other LSI can be used as the hardware resource. A program such as an operating system and an application can be used as the software resource.

The present invention relates to the ion implanter and the ion implantation method.

It should be understood that the invention is not limited to the above-described embodiment, but may be modified into various forms on the basis of the spirit of the invention. Additionally, the modifications are included in the scope of the invention.

What is claimed is:

1. An ion implanter comprising:
an ion source that generates ions;
a beam transport device that transports an ion beam configured by the ions generated by the ion source to an implantation processing chamber;
a workpiece holding device that is disposed in the implantation processing chamber and that holds a workpiece irradiated with the ion beam;
a tilt angle adjusting device that adjusts a tilt angle of the workpiece held by the workpiece holding device;
one or a plurality of processors; and
one or a plurality of memories in which a program that is executable by the one or the plurality of processors is stored,
wherein the program includes the following steps of (a) to (d):
(a) adjusting, based on information on a first implantation angle of the ion beam with respect to the workpiece determined in advance in a first region of a processing surface of the workpiece, a tilt angle of the workpiece holding device to a first tilt angle corresponding to the first implantation angle with the tilt angle adjusting device,
(b) transporting the ion beam with the beam transport device and irradiating the first region of the processing surface of the workpiece held at the first tilt angle by the workpiece holding device with the ion beam,
(c) adjusting, based on information on a second implantation angle, which is different from the first implantation angle of the ion beam with respect to the workpiece and which is determined in advance in a second region different from the first region of the processing surface of the workpiece, the tilt angle of the workpiece holding device to a second tilt angle corresponding to the second implantation angle, which is different from the first tilt angle, with the tilt angle adjusting device, and
(d) transporting the ion beam with the beam transport device and irradiating the second region of the processing surface of the workpiece held at the second tilt angle by the workpiece holding device with the ion beam.

2. The ion implanter according to claim 1,
wherein in the step of (b), the first region is irradiated with the ion beam at the first implantation angle due to the tilt angle adjusting device, and
in the step of (d), the second region is irradiated with the ion beam at the second implantation angle due to the tilt angle adjusting device.

3. An ion implanter comprising:
an ion source that generates ions;
a beam transport device that transports an ion beam configured by the ions generated by the ion source to an implantation processing chamber and that includes a beam irradiation angle adjusting device which adjusts an irradiation angle of the ion beam with respect to a workpiece, which is disposed in the implantation processing chamber and irradiated with the ion beam;
a beam irradiation angle acquisition device that measures the ion beam and that acquires information related to the irradiation angle of the ion beam to the workpiece;
a workpiece holding device that holds the workpiece irradiated with the ion beam;
one or a plurality of processors; and
one or a plurality of memories in which a program that is executable by the one or the plurality of processors is stored,
wherein the program includes the following steps of (A) to (E):
(A) measuring the ion beam transported to the implantation processing chamber and acquiring the information related to the irradiation angle of the ion beam to the workpiece with the beam irradiation angle acquisition device,
(B) adjusting, based on information on a first implantation angle of the ion beam with respect to the workpiece determined in advance in a first region of a processing surface of the workpiece and the information related to the irradiation angle acquired in the step of (A), the irradiation angle of the ion beam to a first irradiation angle with the beam irradiation angle adjusting device,
(C) transporting the ion beam with the beam transport device and irradiating the first region of the processing surface of the workpiece held by the workpiece holding device with the ion beam at the first irradiation angle,
(D) adjusting, based on information on a second implantation angle which is different from the first implantation angle of the ion beam with respect to the workpiece and which is determined in advance in a second region different from the first region of the processing surface of the workpiece and the information related to the irradiation angle acquired in the step of (A), the irradiation angle of the ion beam to a second irradiation angle different from the first irradiation angle with the beam irradiation angle adjusting device, and
(E) transporting the ion beam with the beam transport device and irradiating the second region of the processing surface of the workpiece held by the workpiece holding device with the ion beam at the second irradiation angle.

4. The ion implanter according to claim 3,
wherein in the step of (C), as the beam transport device irradiates the first region with the ion beam at the first irradiation angle, irradiation with the ion beam at the first implantation angle is performed, and
in the step of (E), as the beam transport device irradiates the second region with the ion beam at the second irradiation angle, irradiation with the ion beam at the second implantation angle is performed.

5. The ion implanter according to claim 3, further comprising:
a tilt angle adjusting device that adjusts a tilt angle of the workpiece held by the workpiece holding device,
wherein the program includes the following steps of (F) and (G):
(F) adjusting, based on information on the first implantation angle of the ion beam with respect to the workpiece determined in advance in the first region of the processing surface of the workpiece, a tilt angle of the workpiece holding device to a first tilt angle with the tilt angle adjusting device, and
(G) adjusting, based on information on the second implantation angle of the ion beam with respect to the workpiece determined in advance in the second region of the processing surface of the workpiece, the tilt angle of the workpiece holding device to a second tilt angle with the tilt angle adjusting device,
in the step of (C), the first region is irradiated with the ion beam at the first implantation angle through the steps of (B) and (F), and
in the step of (E), the second region is irradiated with the ion beam at the second implantation angle through the steps of (D) and (G).

6. The ion implanter according to claim 1,
wherein the ion beam is a ribbon beam having a size larger than the workpiece in one direction perpendicular to a traveling direction thereof.

7. The ion implanter according to claim 1,
wherein the beam transport device further includes a beam scan device that performs scanning with the ion beam in one direction perpendicular to a traveling direction thereof, and
the ion beam is a spot beam.

8. The ion implanter according to claim 1,
wherein during movement of the workpiece with respect to the ion beam, the tilt angle adjusting device changes a first axis tilt angle of the workpiece about a first axis perpendicular to a movement direction of the workpiece.

9. The ion implanter according to claim 1,
wherein during movement of the workpiece with respect to the ion beam, the tilt angle adjusting device changes a second axis tilt angle of the workpiece about a second axis parallel to a movement direction of the workpiece.

10. The ion implanter according to claim 1,
wherein an irradiation position of the ion beam on the workpiece of which the tilt angle is adjusted by the tilt angle adjusting device is arranged on a straight line parallel to a movement direction of the workpiece.

11. The ion implanter according to claim 3,
wherein the beam irradiation angle acquisition device includes an irradiation angle distribution acquisition unit that acquires a distribution depending on an irradiation position of the irradiation angle of the ion beam at the irradiation position with respect to the workpiece.

12. The ion implanter according to claim 1, further comprising:
a twist angle changing mechanism that changes a twist angle about a third axis in a normal direction of the processing surface of the workpiece during movement of the workpiece with respect to the ion beam.

13. The ion implanter according to claim 1,
wherein the tilt angle adjusting device is a beam irradiation angle adjusting device that adjusts an irradiation angle of the ion beam during movement of the workpiece with respect to the ion beam.

14. The ion implanter according to claim 13,
wherein during the movement of the workpiece with respect to the ion beam, the beam irradiation angle adjusting device changes the irradiation angle of the ion beam about a first axis perpendicular to a movement direction.

15. The ion implanter according to claim 13,
wherein during the movement of the workpiece with respect to the ion beam, the beam irradiation angle adjusting device changes the irradiation angle of the ion beam about a second axis parallel to a movement direction.

16. The ion implanter according to claim 13,
wherein the beam irradiation angle adjusting device is a beam deflection device that deflects the ion beam in one direction perpendicular to a traveling direction thereof during the movement of the workpiece with respect to the ion beam.

17. The ion implanter according to claim 16,
wherein the beam deflection device changes a deflection angle of the ion beam depending on an irradiation position of the ion beam on the workpiece.

18. The ion implanter according to claim 13,
wherein the beam irradiation angle adjusting device is a convergent/divergent angle changing device that changes a convergent/divergent angle of the ion beam during the movement of the workpiece with respect to the ion beam.

19. The ion implanter according to claim 18,
wherein the convergent/divergent angle changing device changes the convergent/divergent angle of the ion beam depending on an irradiation position of the ion beam on the workpiece.

20. The ion implanter according to claim 18,
wherein the convergent/divergent angle changing device is configured by at least any one of a parallelizing device that is capable of adjusting parallelism of the ion beam and a lens device that can adjust convergence/divergence of the ion beam.

21. An ion implantation method in an ion implanter including
an ion source that generates ions,
a beam transport device that transports an ion beam configured by the ions generated by the ion source to an implantation processing chamber,
a workpiece holding device that is disposed in the implantation processing chamber and that holds a workpiece irradiated with the ion beam, and
a tilt angle adjusting device that adjusts a tilt angle of the workpiece held by the workpiece holding device,
the ion implantation method comprising performing the following steps of (a) to (d):
(a) adjusting, based on information on a first implantation angle of the ion beam with respect to the workpiece determined in advance in a first region of a processing surface of the workpiece, a tilt angle of the workpiece holding device to a first tilt angle corresponding to the first implantation angle with the tilt angle adjusting device;
(b) transporting the ion beam with the beam transport device and irradiating the first region of the processing surface of the workpiece held at the first tilt angle by the workpiece holding device with the ion beam;
(c) adjusting, based on information on a second implantation angle, which is different from the first implantation angle of the ion beam with respect to the workpiece and which is determined in advance in a second region different from the first region of the processing surface of the workpiece, the tilt angle of the workpiece holding device to a second tilt angle corresponding to the second implantation angle, which is different from the first tilt angle, with the tilt angle adjusting device; and
(d) transporting the ion beam with the beam transport device and irradiating the second region of the processing surface of the workpiece held at the second tilt angle by the workpiece holding device with the ion beam.

22. An ion implantation method in an ion implanter including:
an ion source that generates ions,
a beam transport device that transports an ion beam configured by the ions generated by the ion source to an implantation processing chamber and that includes a beam irradiation angle adjusting device which adjusts an irradiation angle of the ion beam with respect to a workpiece, which is disposed in the implantation processing chamber and irradiated with the ion beam,
a beam irradiation angle acquisition device that measures the ion beam and that acquires information related to the irradiation angle of the ion beam to the workpiece, and
a workpiece holding device that holds the workpiece irradiated with the ion beam,
the ion implantation method comprising performing the following steps of (A) to (E):
(A) measuring the ion beam transported to the implantation processing chamber and acquiring the information related to the irradiation angle of the ion beam to the workpiece with the beam irradiation angle acquisition device;
(B) adjusting, based on information on a first implantation angle of the ion beam with respect to the workpiece determined in advance in a first region of a processing surface of the workpiece and the information related to the irradiation angle acquired in the step of (A), the irradiation angle of the ion beam to a first irradiation angle with the beam irradiation angle adjusting device;
(C) transporting the ion beam with the beam transport device and irradiating the first region of the processing surface of the workpiece held by the workpiece holding device with the ion beam at the first irradiation angle;
(D) adjusting, based on information on a second implantation angle which is different from the first implantation angle of the ion beam with respect to the workpiece and which is determined in advance in a second region different from the first region of the processing surface of the workpiece and the information related to the irradiation angle acquired in the step of (A), the irradiation angle of the ion beam to a second irradiation angle different from the first irradiation angle with the beam irradiation angle adjusting device; and
(E) transporting the ion beam with the beam transport device and irradiating the second region of the processing surface of the workpiece held by the workpiece holding device with the ion beam at the second irradiation angle.

23. The ion implantation method according to claim 21, further comprising:
performing a step of acquiring physical property values in the first region and the second region after irradiating with the ion beam.

24. The ion implantation method according to claim 23, further comprising:
performing a step of deriving a correlation between each of the physical property values acquired in the first region and the second region and each of the first implantation angle and the second implantation angle in the first region and the second region.
